(19) United States
(12) Patent Application Publication
(10) Pub. No.: US 2026/0359512 A1
(43) Pub. Date: Nov. 12, 2026

(54) COMPOSABLE SELF-MODELING CYBER-PHYSICAL SYSTEMS

(71) Applicant: TIMELIKE SYSTEMS INC., Albuquerque, NM (US)

(72) Inventors: Stephen Coy, Los Ranchos, NM (US); Gregory Gershanok, Honolulu, HI (US)

(21) Appl. No.: 19/125,080

(22) PCT Filed: Oct. 27, 2023
(86) PCT No.: PCT/US2023/078100

§ 371 Date: Apr. 28, 2025

Related U.S. Application Data
(60) Provisional application No. 63/420,483, filed on Oct. 28, 2022.

(51) Int. Cl. G06F 30/20; G06F 8/60

(52) U.S. Cl. CPC G06F 30/20; G06F 8/60

(57) ABSTRACT

Embodiments are directed to a system for creating, operating, and simulating composable self-modeling cyber-physical systems, where the self-modeling cyber-physical systems support auto-generation of a predictive digital twin for itself and where operation of those systems involves model-based, decision-making using the autogenerated predictive digital twins.

### CROSS REFERENCE TO RELATED PATENT APPLICATIONS

This application claims the priority and benefit under 35 U.S.C. § 119(e) of U.S. Provisional Patent Application Ser. No. 63/420,483, filed Oct. 28, 2022, entitled “SCALABLE MODEL-BASED OPERATING SYSTEM FOR DISTRIBUTED CYBERNETIC SYSTEMS OF SYSTEMS.” U.S. Provisional Patent Application Ser. No. 63/420,483 is herein incorporated by reference in its entirety.

### TECHNICAL FIELD

Embodiments are generally related to the fields of computer modeling, and the development, implementation, and operation of cyber-physical systems. Embodiments are generally related to the fields of computer modeling, and the development, implementation, and operation of cybernetic systems. Embodiments are also related to the field of machine learning. Embodiments are further related to the field of computer devices and mobile devices used for software framework, which is designed to efficiently perform multiple concurrent model-based optimization tasks in a high performance computing environment. Embodiments are also related to methods, systems, and devices for complex computer modeling.

### BACKGROUND

Many experts believe we are rapidly approaching an inevitable “technological singularity”, often described more or less as a hypothetical point in time at which technological growth becomes uncontrollable and irreversible, resulting in unforeseeable changes to human civilization. One possibility is that this results a powerful superintelligence that qualitatively far surpasses all human intelligence.

Intelligence can more accurately be considered a very sophisticated tool used for a purpose. The purpose of intelligence, in this context, is to enable a decision-making entity to make “good” decisions, i.e., to make decisions which maximize the likelihood of consequences the entity wants, and/or minimize the likelihood of consequences the entity doesn't want. In the case of biological entities, which have developed intelligence through the process of evolution, what the entity wants, reflects the fundamental imperatives of genetic survival (survive, reproduce, and have offspring survive and reproduce), but elaborated according to the particular ecological niche the entity's species inhabits, plus some variation among individuals within a species.

If these experts are to be believed, we may be on the verge of creating superintelligence. Some people who have speculated about this, reasoning by analogy based on biological organisms, assume that these entities would have to have some powerful survival drive, and this leads them to speculate that they may see humans as competitors, or inconveniences, or even just a waste of resources, leading to imagined scenarios which tend to end badly for humans.

Often in science fiction scenarios about artificial superintelligent entities, the story assumes that there is only one such entity in existence, the first, and that it can exploit vulnerabilities in computer networks, like a human hacker, but better and faster. But what if, instead, the necessary technology doesn't appear all at once, in just a single place, but instead it is developed over time starting with useful-but-not-superhuman Al agents, used to relieve humans of first very simple tasks, then somewhat less simple, and so forth, so that by the time we develop more-or-less human-competitive Als, there are lots of them resident on the internet-of-things, constantly interacting with one another and with humans.

It is not implausible that a kind of “ecosystem” would then arise, when every human being and every organization made up of human beings-from a small companies up to a nation-states-has its own superintelligent Al looking out for its interests, and all those superintelligent Als know how to talk to one another, buy and sell services from one another, and so forth.

Such a system, once it was up and running, and working properly, ideally would exhibit emergent properties to form a synergistic and self-regulating, complex system that helps to maintain and perpetuate the desired conditions.

As an intermediate step, systems of different kinds will need to able to interact with one another. For example, some systems are made up of different kinds of subsystems, which interact with one another and their environments. Different kinds of systems may exist and interact within the same environment.

In recent years, it has become increasingly widely recognized that we need better tools for modeling large, complex heterogeneous systems, systems which can involve effects and interactions that cut across many different scientific and engineering domains. This is especially true for systems combining cyber-physical or cyber-mechanical systems, involving mechanical interactions, sensors, computers, communication networks, and embedded software.

Accordingly, there is a need in the art for cyber-physical systems which can support self-modeling (e.g., auto-generation of digital twins) for use in model-based decision-making, and/or model-based predictive control, as well as methods and system for modeling large, complex heterogeneous systems as disclosed herein.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the disclosed embodiments to provide improved methods and systems for combining heterogeneous models. To make informed decisions, it is necessary to model and simulate these interactions. In order to accomplish this one aspect of the embodiments is to combine heterogeneous models. In an embodiment, a single common representation is required which can describe the interactions between these models. Once a satisfactory common representation is determined, in an embodiment, a corresponding open standard can be defined.

In certain embodiments, the system can provide robust support for model based applications including but not limited to: (a) completely general purpose modeling and simulation, (b) full-lifecycle MBE and DevSecOps (DevOps+zero-trust security) for cyber-physical or cybernetic systems, including the actual implementation of all their software components and subsystems, as well as post-deployment operations, maintenance, and evolution over time, (c) model-based decision support for human decision-makers, and (d) model-based decision-making for autonomous systems.

In certain embodiments, the disclosed methods and system comprise a framework for computer modeling and simulation of time-dependent systems and model-based engineering of hardware-software systems. The framework supports modeling of continuous-time, discrete event, and hybrid (continuous/discrete) systems. The framework can further provide a user-friendly connect-the-blocks user interface for creating system models, and a simple spreadsheet like interface for setting up and executing parameter studies. The framework can be used to model virtually any kind of time-dependent system, at any level of fidelity, limited only by the user's knowledge of how the actual system works.

In additional embodiments, the disclosed methods and systems provide a useful foundation for a wide variety of domain-specific modeling tools.

In certain embodiments, the disclosed methods and systems provide a robust general purpose integration platform for independently developed domain-specific modeling tools, enabling system modelers to use the tools they are already familiar with to model those aspects of the system each is well-suited for, and then to combine them into a single integrated model of the whole system.

In an embodiment, a system comprises, a computer system further comprising: at least one processor; and a computer-usable medium embodying computer program code, the computer-usable medium capable of communicating with the at least one processor, the computer program code comprising instructions executable by the at least one processor and configured for: identifying a real-world cyber-physical system, generating a predictive digital twin of the real-world cyber-physical system, generating at least one additional predictive digital twin comprising a copy of the predicative digital twin of the real-world cyber-physical, simulating changes to the real-world cyber-physical system using the predictive digital twin(s), and uploading software-only components to the real-world cyber-physical system based on the results of the simulations. In an embodiment, generating a predictive digital twin of the real-world cyber-physical system further comprises automatically generating the predictive digital twin.

In an embodiment, automatically generating the predictive digital twin of the real-world cyber-physical system further comprises creating copies of software-only components of the real-world cyber-physical system. In an embodiment, automatically generating the predictive digital twin further comprises modeling at least one computer associated with the real-world cyber-physical system used to run the software-only components of the real-world cyber-physical system. In an embodiment, modeling computers associated with the real-world cyber-physical system comprises requisitioning a stateful container and putting the stateful container into a same state by copying all files from a given software container in the real-world cyber-physical system to the modeled computer in the predictive digital twin of the real-world cyber-physical system. In an embodiment, automatically generating the predictive digital twin of the real-world cyber-physical system further comprises generating a software model of each hardware component used in the real-world cyber physical system. In an embodiment, generating the software model of each hardware component used in the real-world cyber-physical system using run-time accessible state information from the real-world cyber physical system. In an embodiment, automatically generating the predictive digital twin of the real-world cyber-physical system further comprises modeling a communications network of the real-world cyber-physical system. In an embodiment, modeling a communications network of the real-world cyber-physical system further comprises artificially imposing limitations on corresponding communications links within the predictive digital twin. In an embodiment, simulating changes to the real-world cyber-physical system further comprises simulating perturbations to the cyber-physical system. In an embodiment, simulating changes to the real-world cyber-physical system further comprises simulating different operating conditions of the real-world cyber-physical system. In an embodiment, the computer system further comprises a GUI.

In another embodiment, a computer modeling system comprises a computer system further comprising: at least one processor and a computer-usable medium embodying computer program code, the computer-usable medium capable of communicating with the at least one processor, the computer program code comprising instructions executable by the at least one processor and configured for generating a predictive digital twin of a real-world cyber-physical system, wherein the real-world cyber-physical system is configured to auto-generate the predictive digital twin of itself and wherein the cyber-physical system is configured to be hierarchically joined with additional cyber-physical systems capable of auto generating additional predictive digital twins of themselves. In an embodiment, the computer modeling system is further configured for embedding the predictive digital twin in a model virtual world. In an embodiment, the model virtual world comprises at least one of a model of an environment, a model of physical devices in the environment, a model of computer systems in the environment, a model of network components associated with the computer systems and a copy of software associated with the computer systems. In an embodiment, the computer modeling system is further configured for generating at least one additional predictive digital twin comprising a copy of the predicative digital twin of the real-world cyber-physical. In an embodiment, the computer modeling system is further configured for simulating changes to the real-world cyber-physical system using the predictive digital twin(s) and uploading software-only components to the real-world cyber-physical system based on the results of the simulations. In an embodiment, simulating changes to the real-world cyber-physical system further comprises at least one of simulating perturbations to the cyber-physical system and simulating different operating conditions of the real-world cyber-physical system.

In another embodiment, a computer implemented method comprises generating a predictive digital twin of a real-world cyber-physical system, simulating changes to the real-world cyber-physical system in a virtual world using the predictive digital twin, and uploading software-only components to the real-world cyber-physical system based on the results of the simulations. In an embodiment, the computer implemented method further comprises automatically generating a predictive digital twin.

### BRIEF DESCRIPTION OF THE FIGURES

The accompanying figures, in which like reference numerals refer to identical or functionally similar elements throughout the separate views and which are incorporated in and form a part of the specification, further illustrate the embodiments and, together with the detailed description, serve to explain the embodiments disclosed herein.

FIG. 1 depicts a block diagram of a computer system which is implemented in accordance with the disclosed embodiments;

FIG. 2 depicts a graphical representation of a network of data-processing devices in which aspects of the present embodiments may be implemented;

FIG. 3 depicts a computer software system for directing the operation of the data-processing system depicted in FIG. 1, in accordance with an example embodiment;

FIG. 4 depicts aspects of a general systems theory, in accordance with the disclosed embodiments;

FIG. 5A depicts aspects of a system framework, in accordance with the disclosed embodiments;

FIG. 5B depicts aspects of a system framework, in accordance with the disclosed embodiments;

FIG. 6A-6F depicts a method for on-demand auto-generation of predictive digital twins for cyber-physical or cybernetic systems, in accordance with the disclosed embodiments.

FIG. 7 depicts details of the method of auto-generation of the predictive digital twin, in accordance with the disclosed embodiments;

FIG. 8 depicts an exemplary diagram of system architecture, in accordance with the disclosed embodiments;

FIG. 9A depicts aspects of implementation of the disclosed systems and methods, in accordance with the disclosed embodiments; and

FIG. 9B depicts aspects of implementation of the disclosed systems and methods, in accordance with the disclosed embodiments.

### DETAILED DESCRIPTION

The particularities of the following descriptions are meant to be exemplary, and are provided to illustrate one or more embodiments and are not intended to limit the scope thereof.

Such exemplary embodiments are more fully described hereinafter, including reference to the accompanying drawings, which show illustrative embodiments. The systems and methods disclosed herein can be embodied in various ways and should not be construed as limited to the embodiments set forth herein. Specifications are provided so that this disclosure will be thorough and complete, and will fully convey the scope of the embodiments to those skilled in the art. Like reference numeral may refer to like elements throughout.

The terminology used herein is for the purpose of describing particular embodiments only and is not intended to be limiting. As used herein, the singular forms such as “a”, “an”, and “the” are intended to include plural forms as well, unless context clearly indicates otherwise. Likewise, the terms “comprise,” “comprises” and/or “comprising,” as used herein, specify the presence of stated features, integers, steps, operations, elements, and/or components, but do not preclude the presence or addition of other features, integers, steps, operations, elements, components, and/or groups thereof.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit, and scope of the invention. All such similar substitutes and modifications apparent to those skilled in the art are deemed to be within the spirit, scope and concept of the invention as defined by the appended claims.

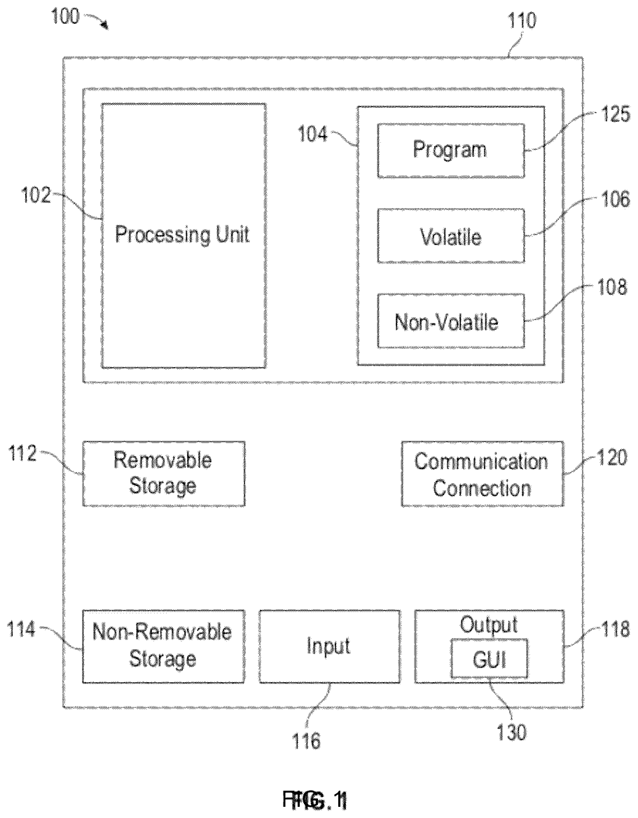

FIGS. 1-3 are provided as exemplary diagrams of data-processing environments in which embodiments of the present invention may be implemented. It should be appreciated that FIGS. 1-3 are only exemplary and are not intended to assert or imply any limitation with regard to the environments in which aspects or embodiments of the disclosed embodiments may be implemented. Many modifications to the depicted environments may be made without departing from the spirit and scope of the disclosed embodiments.

A block diagram of a computer system 100 that executes programming for implementing parts of the methods and systems disclosed herein is shown in FIG. 1. A computing device in the form of a computer 110 configured to interface with sensors, peripheral devices, and other elements disclosed herein may include one or more processing units 102, memory 104, removable storage 112, and non-removable storage 114. Memory 104 may include volatile memory 106 and non-volatile memory 108. Computer 110 may include or have access to a computing environment that includes a variety of transitory and non-transitory computer-readable media such as volatile memory 106 and non-volatile memory 108, removable storage 112 and non-removable storage 114. Computer storage includes, for example, random access memory (RAM), read only memory (ROM), erasable programmable read-only memory (EPROM) and electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage, or other magnetic storage devices, or any other medium capable of storing computer-readable instructions as well as data including image data.

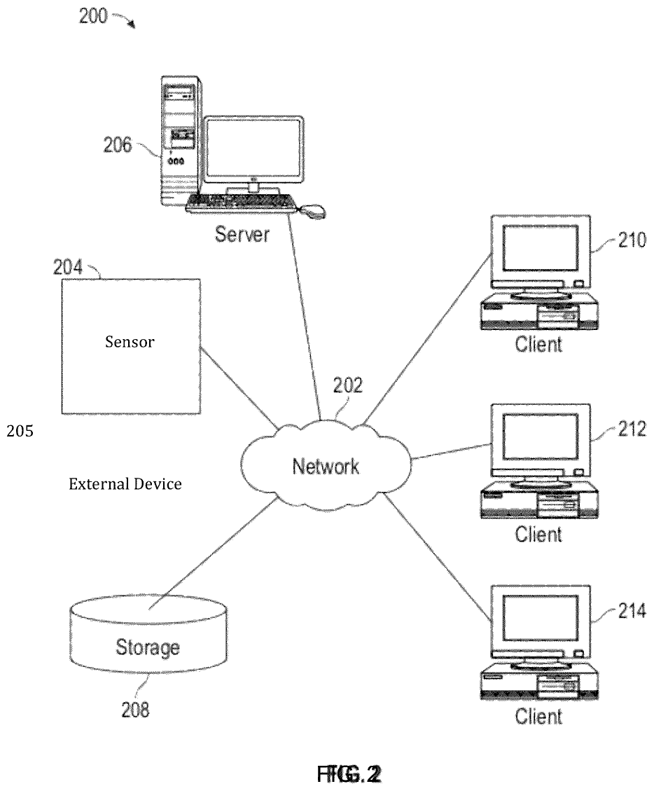

Computer 110 may include or have access to a computing environment that includes input 116, output 118, and a communication connection 120. The computer may operate in a networked environment using a communication connection 120 to connect to one or more remote computers, remote sensors, detection devices, hand-held devices, multi-function devices (MFDs), mobile devices, tablet devices, mobile phones, Smartphones, or other such devices. The remote computer may also include a personal computer (PC), server, router, network PC, RFID enabled device, a peer device or other common network node, or the like. The communication connection may include a Local Area Network (LAN), a Wide Area Network (WAN), Bluetooth connection, or other networks. This functionality is described more fully in the description associated with FIG. 2 below.

Output 118 is most commonly provided as a computer monitor, but may include any output device. Output 118 and/or input 116 may include a data collection apparatus associated with computer system 100. In addition, input 116, which commonly includes a computer keyboard and/or pointing device such as a computer mouse, computer track pad, or the like, allows a user to select and instruct computer system 100. A user interface can be provided using output 118 and input 116. Output 118 may function as a display for displaying data and information for a user, and for interactively displaying a graphical user interface (GUI) 130.

Note that the term “GUI” generally refers to a type of environment that represents programs, files, options, and so forth by means of graphically displayed icons, menus, and dialog boxes on a computer monitor screen. A user can interact with the GUI to select and activate such options by directly touching the screen and/or pointing and clicking with a user input device 116 such as, for example, a pointing device such as a mouse and/or with a keyboard. A particular item can function in the same manner to the user in all applications because the GUI provides standard software routines (e.g., module 125) to handle these elements and report the user's actions. The GUI can further be used to display the electronic service image frames as discussed below.

Computer-readable instructions, for example, program module or node 125, which can be representative of other modules or nodes described herein, are stored on a computer-readable medium and are executable by the processing unit 102 of computer 110. Program module or node 125 may include a computer application. A hard drive, CD-ROM, RAM, Flash Memory, and a USB drive are just some examples of articles including a computer-readable medium.

FIG. 2 depicts a graphical representation of a network of data-processing systems 200 in which aspects of the present invention may be implemented. Network data-processing system 200 is a network of computers or other such devices such as mobile phones, smartphones, sensors, detection devices, and the like in which embodiments of the present invention may be implemented. Note that the system 200 can be implemented in the context of a software module such as program module 125. The system 200 includes a network 202 in communication with one or more clients 210, 212, and 214, and external device 205. Network 202 may also be in communication with one or more external devices 205 or sensors 204, servers 206, and storage 208. Network 202 is a medium that can be used to provide communications links between various devices and computers connected together within a networked data processing system such as computer system 100. Network 202 may include connections such as wired communication links, wireless communication links of various types, fiber optic cables, quantum, or quantum encryption, or quantum teleportation networks, etc. Network 202 can communicate with one or more servers 206, one or more external devices 205, and a memory storage unit such as, for example, memory or database 208. It should be understood that the external device 205 may be embodied as a cyber-physical system, device within a cyber-physical system, mobile device, cell phone, tablet device, monitoring device, detector device, sensor microcontroller, controller, receiver, transceiver, or other such device.

In the depicted example, external device 205, server 206, and clients 210, 212, and 214 connect to network 202 along with storage unit 208. Clients 210, 212, and 214 may be, for example, personal computers or network computers, handheld devices, mobile devices, tablet devices, smartphones, personal digital assistants, microcontrollers, recording devices, MFDs, etc. Computer system 100 depicted in FIG. 1 can be, for example, a client such as client 210 and/or 212.

Computer system 100 can also be implemented as a server such as server 206, depending upon design considerations. In the depicted example, server 206 provides data such as boot files, operating system images, applications, and application updates to clients 210, 212, and/or 214. Clients 210, 212, and 214, sensors 204, and external device 205 are clients to server 206 in this example. Network data-processing system 200 may include additional servers, clients, and other devices not shown. Specifically, clients may connect to any member of a network of servers, which provide equivalent content.

In the depicted example, network data-processing system 200 is the Internet with network 202 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers consisting of thousands of commercial, government, educational, and other computer systems that route data and messages. Of course, network data-processing system 200 may also be implemented as a number of different types of networks such as, for example, an intranet, a local area network (LAN), or a wide area network (WAN). FIGS. 1 and 2 are intended as examples and not as architectural limitations for different embodiments of the present invention.

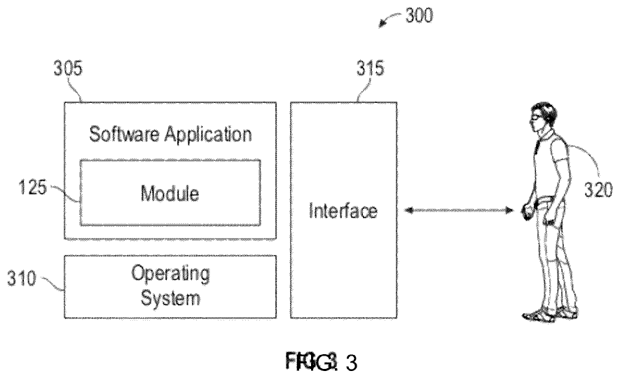

FIG. 3 illustrates a software system 300, which may be employed for directing the operation of the data-processing systems such as computer system 100 depicted in FIG. 1. Software application 305, may be stored in memory 104, on removable storage 112, or on non-removable storage 114 shown in FIG. 1, and generally includes and/or is associated with a kernel or operating system 310 and a shell or interface 315. One or more application programs, such as module(s) or node(s) 125, may be “loaded” (i.e., transferred from removable storage 112 into the memory 104) for execution by the data-processing system 100. The data-processing system 100 can receive user commands and data through user interface 315, which can include input 116 and output 118, accessible by a user 320. These inputs may then be acted upon by the computer system 100 in accordance with instructions from operating system 310 and/or software application 305 and any software module(s) 125 thereof.

Generally, program modules (e.g., module 125) can include, but are not limited to, routines, subroutines, software applications, programs, objects, components, data structures, etc., that perform particular tasks or implement particular abstract data types and instructions. Moreover, those skilled in the art will appreciate that elements of the disclosed methods and systems may be practiced with other computer system configurations such as, for example, hand-held devices, mobile phones, smart phones, tablet devices, multi-processor systems, printers, copiers, fax machines, multi-function devices, data networks, microprocessor-based or programmable consumer electronics, networked personal computers, minicomputers, mainframe computers, servers, medical equipment, medical devices, and the like.

Note that the term module or node as utilized herein may refer to a collection of routines and data structures that perform a particular task or implements a particular abstract data type. Modules may be composed of two parts: an interface, which lists the constants, data types, variables, and routines that can be accessed by other modules or routines; and an implementation, which is typically private (accessible only to that module), and which includes source code that actually implements the routines in the module. The term module may also simply refer to an application such as a computer program designed to assist in the performance of a specific task such as word processing, accounting, inventory management, etc., or a hardware component designed to equivalently assist in the performance of a task.

The interface 315 (e.g., a graphical user interface 130) can serve to display results, whereupon a user 320 may supply additional inputs or terminate a particular session. In some embodiments, operating system 310 and GUI 130 can be implemented in the context of a “windows” system. It can be appreciated, of course, that other types of systems are possible. For example, rather than a traditional “windows” system, other operation systems such as, for example, a real time operating system (RTOS) more commonly employed in wireless systems may also be employed with respect to operating system 310 and interface 315. The software application 305 can include, for example, module(s) 125, which can include instructions for carrying out steps or logical operations such as those shown and described herein.

The following description is presented with respect to embodiments of the present invention, which can be embodied in the context of, or require the use of a data-processing system such as computer system 100, in conjunction with program module 125, and data-processing system 200 and network 202 depicted in FIGS. 1-3. The present invention, however, is not limited to any particular application or any particular environment. Instead, those skilled in the art will find that the systems and methods of the present invention may be advantageously applied to a variety of system and application software including database management systems, word processors, and the like. Moreover, the present invention may be embodied on a variety of different platforms including Windows, Macintosh, UNIX, LINUX, Android, Arduino and the like. Therefore, the descriptions of the exemplary embodiments, which follow, are for purposes of illustration and not considered a limitation.

In certain embodiments, the disclosed systems and methods are directed to the creation, operation, and simulation of composable “self-modeling” cyber-physical systems. A “self-modeling” cyber-physical system is a cyber-physical system that can support on-demand auto-generation of a predictive digital twin (i.e., an executable computer model) for itself. Furthermore, a composable self-modeling cyber-physical system, means that those cyber-physical systems can be composed-connected together, generally in a hierarchical assemblage-to form a larger cyber-physical system, and the resulting larger cyber-physical system can also support on-demand auto-generation of a predictive digital twin for itself. Operation of such cyber-physical systems may involve model-based decision-making, which can make use of these autogenerated digital twins of the cyber-physical systems. To support this kind of decision-making, computer models of the surrounding environments within which these systems exist, are necessary. Aspects of these embodiments are discussed in more detail below.

In the embodiments disclosed herein, a system, method, and apparatus can comprise computer implemented modeling. In the real world, many different kinds of systems interact with one another. To make informed decisions, it would be advantageous to have a model in order to simulate these interactions. To do this, it is necessary to be able to combine heterogeneous models. The disclosed embodiments represent a single common representation which can describe the interactions between these models. Once the common representation is established, further aspects of the embodiments can include a corresponding open standard.

There are many different kinds of systems, both natural and man-made, and essentially all of them can interact with one another, either directly or indirectly. And now, with the advent of the Internet of Things, signals can propagate all the way around the planet in just a fraction of a second, offering unprecedent connection between various systems. Embodiments are thus directed to combining models of any of the many different kinds of systems that can be found on or near Earth including but not limited to Man-made systems, including critical infrastructure, such as the IoT; biological systems, including people, plants, animals, and pathogens; other natural systems, including climate and weather; social systems, including families, corporations, and nation-states, generally referred to as cyber-physical systems. It is another aspect to be able to model each of these systems at a desired level of fidelity as appropriate to the corresponding application.

As disclosed herein, combining heterogeneous models can include identification of a common representation which can be used to describe the interactions between the models. For example, multi-physics tools combine models from different physical domains using generalized Partial Differential Equations (PDEs). Similarly, the Functional Mockup Interface (FMI) standard combines different models by assuming that their interactions can be modeled as Ordinary Differential Equations (ODEs). The disclosed embodiments include a common representation which can describe all of the different kinds of interactions that can take place between all of the different kinds of systems to be modeled.

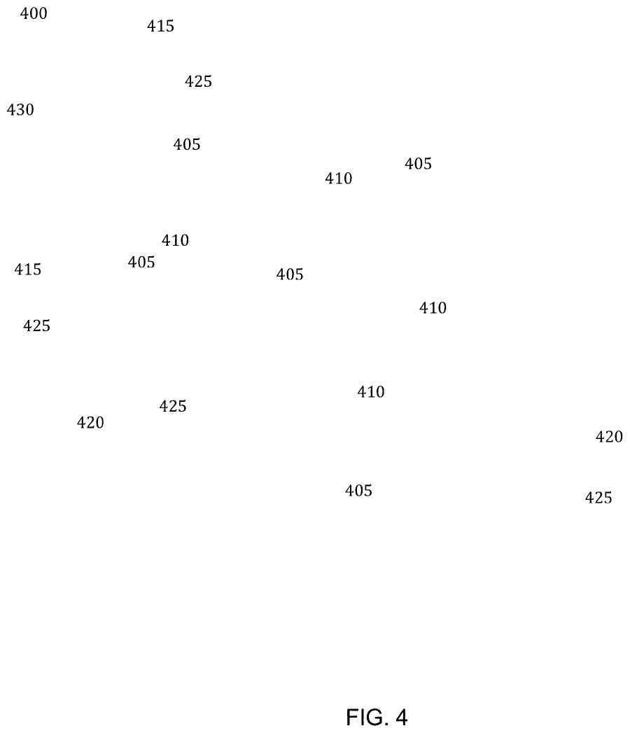

As a starting point consider the general systems theory. FIG. 4 includes a diagram 400 illustrating a cyber physical system 440 associated with the disclosed embodiments, which can include various components 405, connected by interrelationships 410. Inputs 415 are illustrated as well as outputs 420 from the components 405 with the interfaces 425 illustrated by the intersection of the input and output arrows with the boundary. The disclosed embodiments provide a framework based on this understanding of the interaction of cyber-physical systems, that is carefully crafted to preserve its full generality.

In certain embodiments, the instantaneous state of any system can be adequately described in terms of a set of generalized variables, where the instantaneous value of each variable can be represented as instantaneous state of some software object, defined in some object-oriented programming language. This is illustrated in Equation (1):

\vec{x}={x₁, x₂, . . . }, where xᵢ ∈{all possible states for all possible OOP objects} (1)

The time evolution of the system's state can be described in terms of causal relationships among its variables, meaning that the value of any given variable at some time t can depend only on the values of itself and/or other variables at the same or earlier times, never later, as illustrated in equation (2):

\vec{x}(t)=ƒₓ(\vec{x}(t′∈[−∞:t])) (2)

Note that this can include not only mathematical relationships (ODEs, DAEs, PDEs, etc.), but also computer algorithms, communications networks, etc.

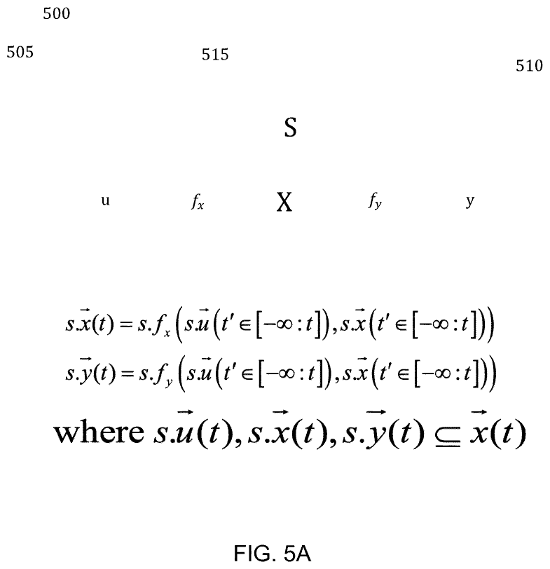

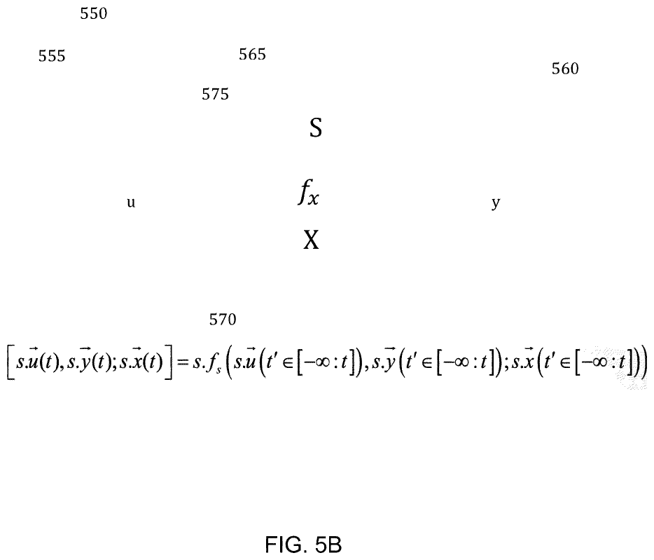

FIG. 5A illustrates a system 500 with components realized with a computer, including inputs 505, outputs 510, and internal states 515. The system 500 illustrates an exemplary embodiment, where inputs 505 and outputs 510 are ready only. However, this isn't strictly required. FIG. 5B illustrates aspects of a more general system 550, with inputs 555, outputs 560 and states 515. This embodiment is more general because it allows for the possibility that some inputs 555 and outputs 560 may be read-write. In addition, the internal state 570 is encapsulated inside the causal relationship that defines the system's behavior f(x) 575.

In certain embodiments, a system and associated computer implemented method are disclosed. The system generally includes a computer system further comprising, one or more processors configured to implement various software implementations. The system can include a GUI, or in other embodiments, all operations can be handled by API calls. The system further includes a computer-usable medium embodying computer program code, the computer-usable medium capable of communicating with the one or more processors, the computer program code comprising instructions executable by the at least one processor and configured for: identifying a real-world cyber-physical system, generating a predictive digital twin of the real-world cyber-physical system, generating at least one additional predictive digital twin comprising a copy of the predicative digital twin of the real-world cyber-physical, simulating real-world perturbations to the cyber-physical system and/or different possible operating conditions using the predictive digital twin(s). and uploading software-only components to the real-world cyber-physical system based on the results of those simulations. Aspects of this basic system and associated method are detailed herein.

For example, aspects of the disclosed embodiments related to the on demand auto-generation of predictive digital twins for cyber physical systems are disclosed. Predictive digital twins of or cyber-physical systems can be extremely useful in the context of the disclosed embodiments, According to the methods disclosed, the system can reduce the incremental cost of constructing high-fidelity digital twins of complex cyber-physical or cybernetic systems by several orders of magnitude; completely eliminate the requirement to maintain a separate digital twin, plus all the related costs and logistical complexities; and make more feasible some very important and very challenging digital twin use cases, e.g. model-based decision support for real-time operations of complex or cybernetic systems.

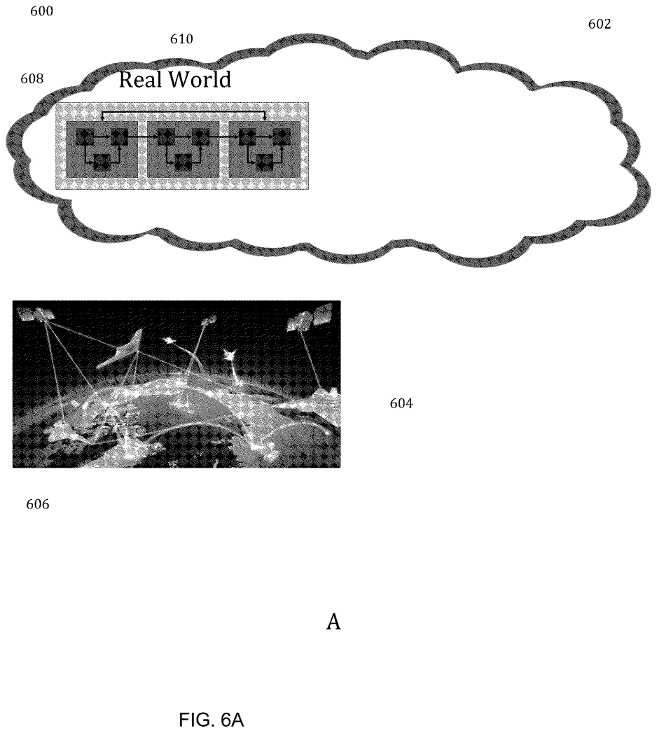

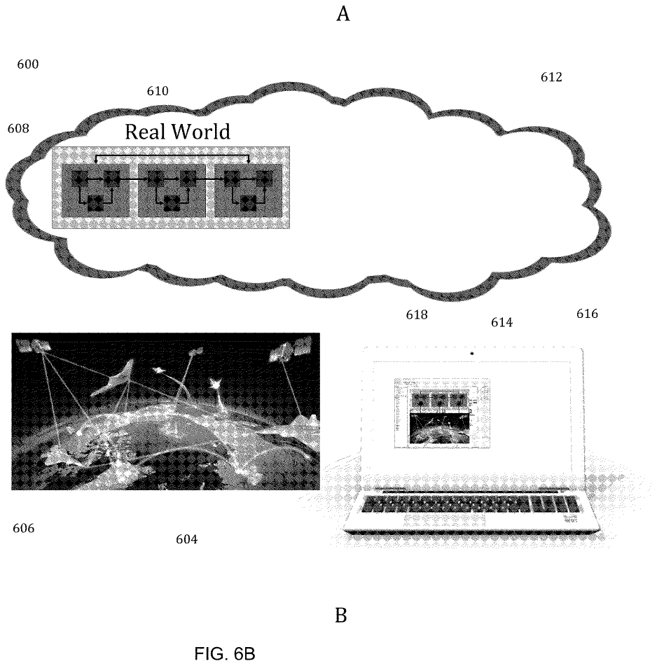

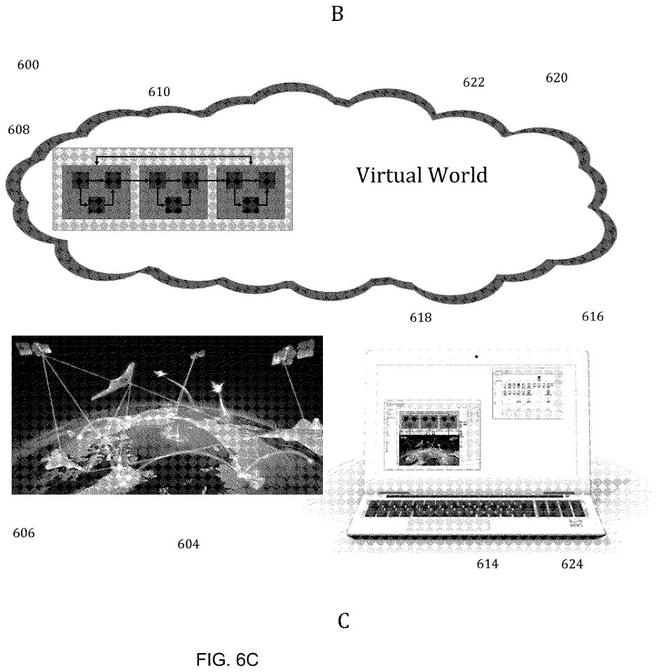

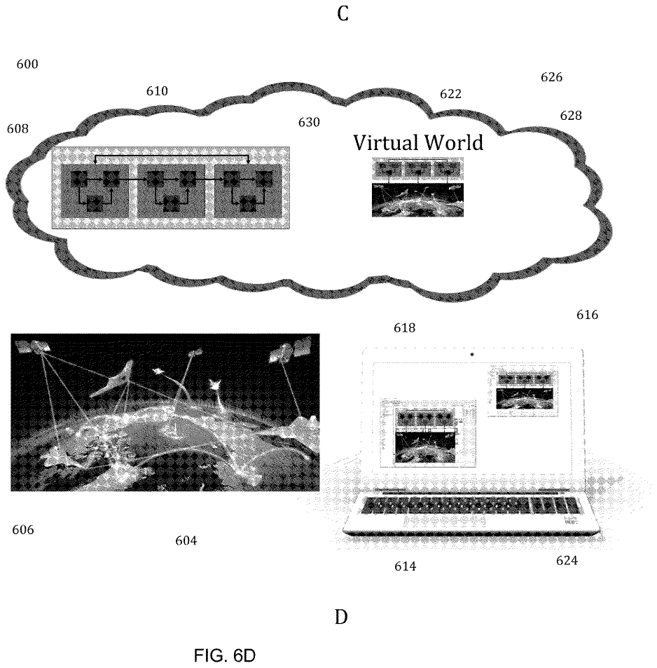

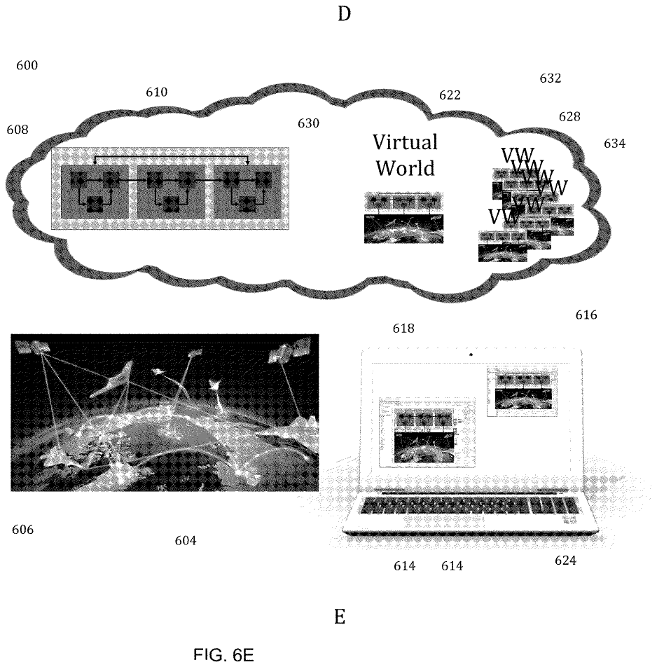

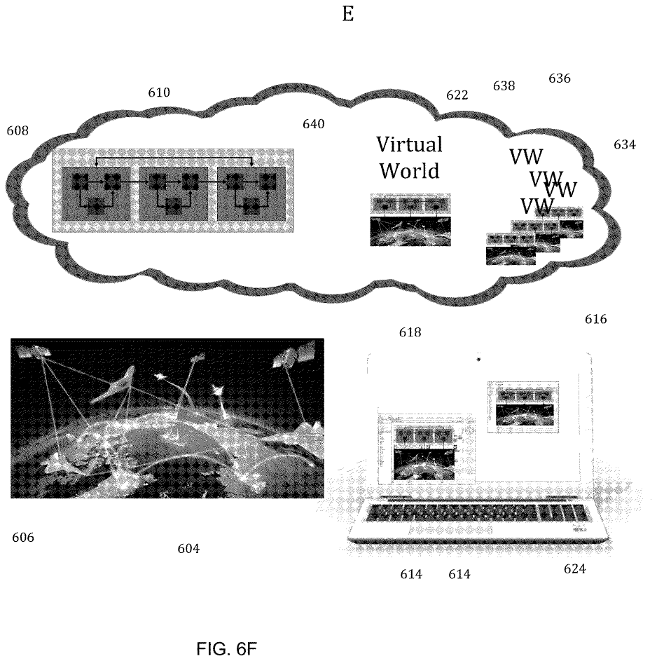

FIG. 6A-6F illustrate a method 600 associated with on-demand auto-generation of predictive digital twins for or cyber-physical systems. It should be understood that this method is illustrated from a user's perspective. However, the disclosed embodiments, can provide a visual programming environment which can be used to inspect and/or modify both (a) real-world or cybernetic/cyber-physical systems which have been implemented, and (b) computer models of causal systems, including cyber-physical or cybernetic systems and their environments, which have been implemented and/or integrated using the disclosed framework.

The method 600 starts at diagram 602 where a cyber-physical system 604 comprising various real world connected devices 606 and associated computer hardware and software 608 controlling those real world connected devices 606. This is most commonly realized with cloud architecture 610.

The cyber-physical system 604 (CPS), has both a “cyber” part, i.e., one or more computer processes 608, running on one or more computers, and a “physical” part, namely one or more physical devices 606 which (a) communicate with (and in general can be controlled by) the cyber part, and (b) interact with the external environment surrounding that CPS (and that surrounding environment may include other CPSs). These physical devices 606 may be small and simple, e.g., individual sensors and actuators, or arbitrary large and complex, up to and including complete CPSs in themselves. That is, CPSs can be, and very often are nested, forming containership hierarchies of CPSs, as illustrated by computer processes 608.

The computers on which the computer processes 608 that make up the cyber part of a CPS 604 may or may not be considered as belonging to that CPS; in some cases they will belong to the CPS-these can be thought of as “dedicated” computers-but in other cases they may be shared resources, e.g. when many CPSs make use of the same shared compute clusters, resident somewhere in the multicloud 610, to offload computation required to support model-based decision-making.

The method progresses from FIG. 6A to FIG. 6B as illustrated by progression A. At this step 612, auto-generation of the digital twin 614 is triggered. This can be accomplished, in some embodiments, by a user command (the assumption being that the given user has the requisite authority/permissions to (a) tell that CPS 604 when to generate a digital twin 614 for itself, and (b) to write to memory on a computer 616 where the auto-generated digital twin can be stored. The CPS 604 then generates a serialized datastream 618 containing all of the information needed to construct the requested digital twin 614, and that serialized data 618 can be stored at a specified memory location (e.g., on computer 616). In general, this could be on the same computer on which the cyber parts of the CPS 604 are running, or a different one. At this point the digital twin 614 exists as a static set of data recorded in memory.

The method progresses from FIG. 6B to FIG. 6C as illustrated by progression B. At this step 620, the digital twin 614 needs to be deserialize to form a “live” model which resides inside a running computer process. In most cases, this includes embedding the digital twin of the CPS within a larger model, which also includes a model of its environment. The auto-generation process only results in the digital twin 614 of the CPS 604 itself; in general, another process is required to create the model of the surrounding environment. Thus, at step 620 a virtual world 622 can be created. The virtual world is a simulation closely or exactly mirroring the real world, or some possible hypothetical or counter-factual variation of the real world.

An aspect of the embodiments is the ability to auto-generate a predictive digital twin (computer model), on demand. The CPS(s) are “composable”, meaning they can be composed together, hierarchically, to form larger CPSs which will then also be capable of auto-generating digital twins of themselves.

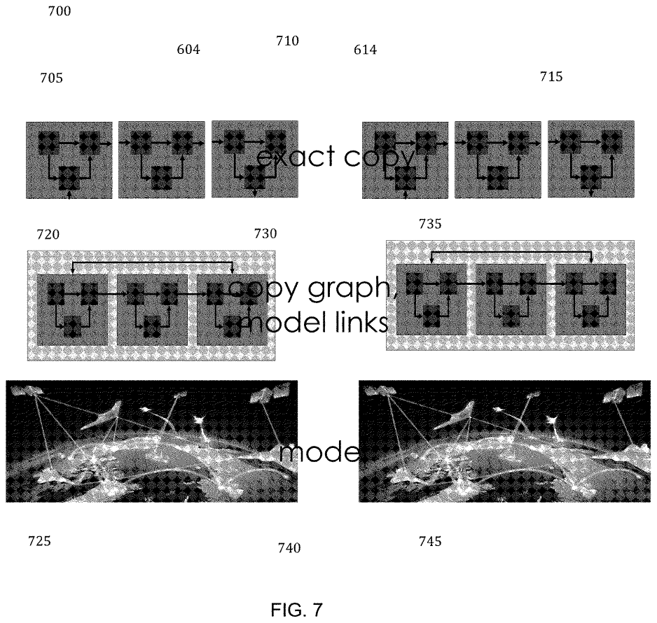

The method progresses from FIG. 6C to FIG. 6D as illustrated by progression C. At this step 626 a digital twin 628 can be autogenerated as illustrated by arrow 630. Auto-generation is an important aspect of the disclosed embodiments. FIG. 7 illustrates steps 700 required to enable a cyber-physical system 604 to autogenerate a predictive digital twin 628, for itself on demand, as illustrated.

First, it is important to note that the original CPS 604 exists within the real world, whereas the autogenerate digital twin 628 exists within a simulated, or virtual, world 622. And, for it to be useful, the simulated behavior of the autogenerated digital twin 628 within that virtual world 622 must closely resemble the actual behavior of the original cyber-physical system 604 in the real world. The resemblance must be close enough that “what if?” experiments using the digital twin 628 to project the probable consequences of different possible courses of action in the real world are possible, prior to deciding on a course of action in the real world. This means that each aspect of the given cyber-physical system 604 must be modeled with sufficient accuracy. This includes all software 608 (or “cyber”) components of the system 604, all hardware 606 (or “physical components”), and also all the computers on which those software runs, and, in the case of a distributed cyber-physical system, the communications network 610 the various components use to talk to one another. In addition, it is necessary to model the physical environment surrounding the system 604, as well any other systems within that environment with which the original system 604 may interact, directly or indirectly.

As illustrated in FIG. 7, the easiest parts of a cyber-physical system 604 to accurately model are its software components 705. The software components 705 can be copied 710 as copy 715, exactly so that the digital twin 614 uses the exact same software used in the real CPS 604. To make this work properly, each such software component is called in the same sequence, with the same inputs, within the digital twin 614, running within a virtual world 622, as it would be within the real system, running in the real world, in any case where both the real system and the digital twin are starting in the same initial state, and experiencing the same interactions with their respective real and virtual environments. Of course, if the initial state is not perfectly known, and/or if there are any stochastic effects involved, the digital twin 614 can't exactly reproduce the behavior of the real system, and in such cases it can behave in a manner qualitatively and statistically consistent with real system.

There is one case, however, where exact correspondence between the two is possible. In that case the system can record the exact input values received by each software component, and the exact time sequence in which they are received, and then “play back” those same input values, in that same time sequence, when running the simulation. In order to ensure that the exact same computations are reproduced in the exact same time sequence, the time-dependent behavior of all software components, used in both the original cyber-physical system and its auto-generated digital twin, is defined with respect to a virtual lime, which is subject to the system control, rather than real time (also known as “wall clock time”).

In order to be able to support recording and playing back the input values for each software component, and also passing its output values to other software components, and to be able to do this in the most general case, the system can support components with inputs and outputs of any data type.

Another important requirement applicable to the software/cyber components 705 of a cyber-physical system 604, to ensure accurate reproduction of their behavior in simulation, is that they should have no “side effects”. That is, they must have a well-defined interface their set of inputs and outputs-visible to the facility used to generate the digital twin, and they must have no interactions with any other part of the cyber-physical system, or its environment, except via that well-defined interface.

FIG. 7 further illustrates the requirements applicable to the hardware/physical components 725 of the cyber-physical system 604, which are quite different from those for the software/cyber components 705. Unlike software components 705, hardware components 725 cannot simply be copied, nor can they be directly incorporated into an autogenerated digital twin. Instead, for the autogenerated digital twin 614 for the cyber-physical system 604, each hardware component 725 is replaced 740 with a corresponding software model 745, i.e., a digital twin for that one hardware component 725. As in the case of software components, the behavior of digital twin 614 for each hardware component 725 closely resembles the behavior of the real component 725-at least closely enough that the projections made based on simulation runs using those component-wise digital twins will be accurate and reliable enough to be provide useful guidance in decision making.

In an embodiment, this is accomplished by implementing a parameterized software model 745 for each different type of hardware component 725 used in the cyber-physical system 604, which can be fine-tuned to model the current state of any particular instance of that type of component using only run-time accessible state information. That way, whenever it is necessary to autogenerate a digital twin for a cyber-physical system that incorporates one or more hardware components of that type, each such component can provide the information needed to generate a digital twin for it, based on its current state at that moment.

In addition, it is necessary to model the behavior of the computers 720 on which the various software components are running, and the communications network used to enable those software components to communicate with one another. Different computers can differ from one another in many different ways, which requires new methods to generate accurate digital twins for any given computer. The disclosed embodiments make use of software container technology, and, in particular, stateful software containers, such as the Linux containers for cloud computing, and scalable compute clusters, where additional stateful software containers can be requisitioned on demand. Using these methods 730, all computers 720 used in any cyber-physical system for which support on-demand autogeneration of predictive digital twins is required, they must be “wrapped” to act as standard software containers, so that a digital twin computer 735 can be generated for each computer 720 in the real system by requisitioning an identical stateful container, and then putting it into the same state, by copying over all files from the given software container in the real cyber-physical system to its digital twin. Of course, if there is a large amount of data to be copied, this can be an expensive operation. These costs can be kept to a minimum it, for each such container, only the minimum amount of data needed to support its intended function is stored, and where it is necessary to auto-generate a digital twin for the same cyber-physical system more than once, the digital twins for some or all of the software containers used in the real system can be reused, by performing only an incremental update on each, rather than requisitioning a new software container and initializing it from scratch.

Likewise, to model the computer 720 communications network the given cyber-physical system 604 uses to enable its software components, running on various software containers within the real system, to communicate with one another, the above-described digital twins for the individual software containers are used, with added modeling of the characteristics of the comm links in real network—latencies, bit rates, error rates, intermittent availability, etc.—by artificially imposing those same limitations on the corresponding comm links within the digital twin 735 of the cyber-physical system.

The method progresses from FIG. 6D to FIG. 6E as illustrated by progression D. At this step 632, multiple additional copies 634 of the digital twin can be generated. These digital twins 634, allow for the simulation of multiple real-world perturbations to the cyber-physical system 604, but in the virtual world 622, as well as different possible operating conditions. As such various possible scenarios, perturbations, operating conditions, or other such stimulus can be “tested” to find the likely outcome. The use of multiple digital twins means that it is possible to test each perturbation independently ad infinitum, in order to optimize the outcome to anticipate the combination of perturbations, operating conditions, or other such stimulus most likely to result in the desired outcome in the real word.

The method progresses from FIG. 6D to FIG. 6E as illustrated by progression D. At this step 636. Once the best course of action-encoded in modified software-only has been identified, at step 636, modified software-only component systems 638 can be uploaded as illustrated by arrow 640 to computer system 606 of the real world system 604, thus changing the real world behavior of the CPS 604 to follow the chosen course of action. It is noteworthy that the only aspects of the real world CPS 604 that can be modified by the upload 640 are the associated software components 608. However, if the digital twins suggest that modifications of the associated computer systems, network systems, or physical components need also be modified, such changes can be made in the real world CPS 604 in order to change the real world behavior of the CPS 604 to follow the chosen course of action.

It should be appreciated that the cloud architecture illustrated in FIGS. 6A-6F is exemplary. In other embodiments, the same systems can be used at the edge with the steps completed on an internet connected computer system. It should be further appreciated that the systems and methods illustrated, for example, in FIGS. 6A-6E can be used to plan and execute changes not just to the software/cyber parts of the CPS, but also in the hardware/physical parts of the system, and also to its environment; the difference being that changes to the software can be accomplished almost instantaneously, and with very little expenditure of energy or cost, whereas changes to the hardware/physical parts and to its environment require time, expenditure of energy, and (generally) cost.

In practice, the systems and methods illustrated in FIGS. 1-7 are configured to allow a user to “copy/paste” all, or a portion, of the graphical representation of the real physical system into a simulation using a GUI. This can further automatically trigger the on-demand generation of a predictive digital twins—i.e., a computer models—for the selected portion of the real system.

In this process. All of the software components can be copied over directly; all of the hardware components can be replaced by corresponding component-level digital twins, which can be initialized using whatever run-time accessible state information the given hardware component provides. The fundamental requirement is that appropriate component digital twins for all hardware components are available, and that each such hardware component can provide sufficient runtime-accessible state information to instantiate its digital twin.

Once the complete digital twin for the copied portion of the real world system has been created, the user can use it for such things as model-based parameter space exploration and model-based optimization. One application of this capability is to test, debug, and optimize a planned modification to one or more of the real system's software components. Once a decision is made to make the now-tested and optimized modification to the real system, the systems illustrated in FIGS. 1-7 can be configured to allow a user to copy/paste the affected portions back to the window looking at the representation of the real world system. In this operation, the software components are once again copied over directly; the digital twins for the hardware components obviously cannot be copied; instead, they are used for error-checking, to verify that the real system still has the same basic configuration of components as of the time the original copy was performed.

The embodiments disclosed herein are useful for individual people and organizations (e.g., companies, governments, NGOs) that need to make decisions, take actions, and adjust their course of action over time within the context of our complex, interconnected, and rapidly changing world. This can include anyone that will be involved in creating and evolving all the technologies that will link the infrastructure and core capabilities to various user-facing interfaces that will be needed.

To that end the systems and methods disclosed herein provide component-based software technology designed to support: (1) predictive computer modeling of anything-any causal system consistent with the laws of physics, no matter how complex and heterogeneous—at any level of fidelity that may be needed to provide adequate support for whatever decisions the end users may need to make; (2) the design, development, and operation of cyber-physical systems, cybernetic systems, and systems-of-systems, to meet whatever requirements and objectives the end-users may have; and (3) efficient, timely, and flexible model-based decision support for human decision-makers (both individual people making decisions pertinent to their own lives, and organizations made up of various people in various roles making decisions pertinent to purposes of that organization) and decision-making for autonomous systems (to which our end users can delegate certain decision-making tasks).

To do this, every system “user account”, at least for users that wish to publish anything—including both models and endorsements/critiques-can be reliably identified with a unique real world legal entity, and then use verified credentials in order to be able to trace back endorsement/critiques to their source. The system can be “seeded” by assigning high credibility's to certain well-respect entities in certain domains of expertise, e.g., IEEE for engineering, the AMA for medicine, individual universities for verifying what individuals have received what degrees, etc., and then include feedback loops, to refine credibility assessments over time. Furthermore, that whole system can be made fully transparent to users.

FIGS. 1-7 illustrate details of the architecture and methodology for modeling as disclosed herein. The following description provides details relating to the implementation of the disclose systems and methods. It should be understood that certain programming nomenclature is used to describe various programming implementations. The names of objects, routines, libraries, or other such names are meant to be exemplary and other naming conventions can be adopted without departing from the scope disclosed herein. The word “TimeLike” as further used herein refers generally to aspects of the embodiments that are part of the hierarchical system architecture and associated software as disclosed.

The disclosed embodiments can be understood to include some or all of the following design features:
1. In TimeLike, a system may have any number of inputs and outputs, each of which represents a function of time with a specified value-type, where the set of value-types supported is arbitrarily extensible, and may include user-defined types, e.g., classes. (Most hierarchical block diagram tools support either only a single value-type, or else some predefined set of value-types.)
2. In TimeLike, a system's inputs may grant the system either read-only (aka const) or read-write (aka mutable) access to the value of the given input. And, similarly, a system's outputs may grant the other systems with connected inputs either read-only (aka const) or read-write (aka mutable) access to the given output. Where, for consistency, read-write inputs may only be connected to read-write outputs. (Most hierarchical block diagram tools support only read-only access to system inputs.)
3. In TimeLike, a system inputs and outputs may represent either single-valued functions of time or a multi-valued functions of time, where, for consistency, multi-valued outputs may only be connected to multi-valued inputs. (Many hierarchical block diagram tools support only single-valued inputs and outputs.)
4. In TimeLike, a system's behavior, including its interactions with connected systems, may be input-driven, output-driven, event-driven (as in discrete event simulation), continuous-time (as in continuous process simulation) or any combination of the above. In addition, its behavior may be defined, in whole or in part, by the individual behaviors of any subsystems it contains, and the way the inputs and outputs of those subsystems are connected to one another, and to the inputs and outputs of the containing system. (Most hierarchical block diagram tools support only some more restrictive set of subsystem behaviors. In particular, most such tools do not permit a system which contains other systems as subsystems, i.e. a composite system, to also incorporate input-driven, output-driven, event-driven, and/or continuous-time behaviors; instead those tools only support “pure” composite systems, whose behaviors are completely defined by the individual behaviors of any subsystems it contains, and the way the inputs and outputs of those subsystems are connected to one another, and to the inputs and outputs of the containing system.)

In the real world, a system's internal structure and its behavior, including the nature of its interactions with other systems, can change over time. Thus, it is possible to dynamically add and delete subsystems, inputs, outputs, and state variables; make and break input-output connections; and change a system's fundamental behavior (fs). Note that as long as these dynamic changes obey causality, the system as a whole will continue to obey causality.

In order to combine heterogeneous models, each model must be able to provide an interface that complies with the same standard. In certain embodiments, a standard can be open, and can be managed and developed by an appropriate industry organization. A good candidate standard, can be implemented, tested, and shown to work well for all applications of interest.

In exemplary embodiments, aspects disclosed herein can comprise a fully automated computer implemented system and method for adaptive concurrent hierarchical efficient and validated exploitation of resources. This can comprise a software framework, designed to efficiently perform multiple concurrent model-based optimization tasks in a high performance computing environment, as illustrated in FIGS. 1-7.

The system can use adaptive multi-fidelity modeling, using uncertainty quantification to determine when it needs to perform additional higher fidelity runs. In this way, the system “learns” over time, gradually increasing its efficiency. The system can be used for fully automated problem-solving, e.g., for autonomous systems, or it can incorporate humans in the loop, e.g., for model-based engineering, or real-time decision support.

In an exemplary embodiment a hierarchical component-based simulation framework is provided (as illustrated in FIGS. 1-7), in combination with mechanisms designed to support surrogate-based design optimization. The system uses multiple models, at differing levels of fidelity, where a model implemented at an appropriate fidelity for one level may be represented by a faster-running surrogate model at the next level up. Each surrogate model can provide reliable estimates of the output quantities needed at the next level up, with known error bars. Each optimization task can proceed until it converges to within the uncertainty caused by those known error bars. At that point, the system automatically performs additional runs using the full fidelity model(s) to reduce the error bars in the neighborhood of interest. Over time, each surrogate model becomes increasingly accurate in the specific regions most pertinent to the optimization tasks, leading to improved performance. Each surrogate model becomes a persistent asset, increasing in value over time, which can be reused in any number of higher level models, for any number of optimization tasks.

Sensitivity analysis can be used to estimate the incremental “value” of each additional run used to refine a surrogate model in terms of the expected increases in the merit function scores for the affected optimization tasks. The estimated per-run incremental values can be used for the various surrogate models to determine how to most effectively use the available computational resources.

In certain embodiments, the system includes an intra-process component layer—systems, subsystems, inputs, outputs, respondTo—methods and the like. In an embodiment, the inter-process component layer can include a top-to-bottom architecture. This architecture provide robust support for modeling which can include: (a) completely general purpose modeling and simulation, (b) full-lifecycle MBE and DevSecOps (DevOps+zero-trust security) for cyber-physical or cybernetic systems, including the actual implementation of all their software components and subsystems, as well as post-deployment operations, maintenance, and evolution over time, (c) model-based decision support for human decision-makers, and (d) model-based decision-making for autonomous systems.

The disclosed systems can be used to design, implement, and operate complex large-scale cyber-physical or cybernetic systems—or components and subsystems intended for use within such systems—because of its comprehensive end-to-end model-based support for all of the decisions, actions, and activities necessary to the creation, operation, and sustainment of such systems. Additionally, it can be used to model and simulate complex causal systems of any kind, or to integrate sub-models implemented in other more specialized M&S tools into a single, larger system model that cuts across multiple engineering and software disciplines. Aspects can include interoperable models of anything that happens within the Earth's biosphere, or couples into it in any way.

It should be appreciated that, practically speaking, there is only one way to “simulate” non-trivial software, and that is to run the actual software (this is a direct consequence of the well-known “Halting Problem”). Therefore, to accurately model complex cyber-physical or cybernetic systems it is necessary run the actual software. The disclosed architecture can serve as the implementation and/or integration platform.

Aspects of the overall architecture are further detailed herein. In certain embodiments every related software system, large or small, no matter who creates it or owns it, can always exist at some well-defined location within a single, global, single-rooted containership/ownership hierarchy, and the topmost container in that hierarchy will be a special “TimeLike” system which can be maintained. For purposes of this disclosure the top-level container can be referred to as “TimeLike_systems”, because it can contain all TimeLike-based systems. Likewise, the word “TimeLike” as further used herein refers generally to aspects that are part of the hierarchical system architecture and associated software as disclosed.

Even though all TimeLike-based systems will exist within that single global containership hierarchy, which can be owned/controlled as the top-level container, that will not mean that the owner/controller has any visibility or access into any of the many sub-hierarchies that can and will be created; by default, all that is visible is the outside view of the user's top-level TimeLike container, the one that contains all of their stuff. Access into any part of their sub-hierarchy can be selected to be available only if the user makes it visible to the top level owner/controller of the top-level container.

All persistent TimeLike objects can be implemented as “TL_Things”, each of which can exist in either of two states, (a) “active”, when it exists as a running computer process, one which comprises a single instance—a singleton—of either the class TL_Thing, directly, or of some subclass derived from it, or (b) “passive” when it existed as serialized data comprising an instantaneous snapshot of its complete state. When it is a passive state, a TL_Thing can easily be moved or copied from one place to another. This makes it possible, for example, for TL_Things to outlive the computer on which they were originally created.

It should be appreciated that “TL_Thing” is an arbitrary naming convention for a component at the inter-process layer of the disclosed component architecture, and “TL_System” is used for an intra-process layer component. TL_Thing is used mainly because a “TL_Thing” is just a special kind of “TL_System”, i.e., a subclass of TL_System, which can exist either as its own computer process, (when active), or as serialized state snapshot (when passive) and interacts with other such components only by means of discrete messages, sent over a communication network. In some embodiments, each such component can always sit at the top of the TL_Object containership hierarchy within its process. However, in other embodiments each intra-process layer component contains a singleton object, an instance of a special subclass of TL_System, called a “TL_Thing”, but that object does NOT, in general sit at the top of the TL_Object containership hierarchy within that process. Instead, the TL_Object containership hierarchy constitutes that TL_Thing's internal “world model”, and, that world model includes both the TL_Thing itself and its surrounding environment. Furthermore, a TL_Thing's internal model of its surrounding environment can be arbitrarily large, and can grow in both scope and detail over time. Nonetheless, throughout this process, there remains a clear boundary between the “self-model”, i.e., that part of the TL_Object containership hierarchy in the given process that falls inside the TL_Thing itself, versus everything outside of that.

The TL_System class can, implicitly assume, in effect, that it only interacts directly, via its input and output connections, with other TL_Systems in the same process, and in the same thread. It is that assumption which makes it ok to do things like (a) when a system does a get on an input, going back in-line to the system with the connected output and calling its rtor() virtual method, and (b) passing input-output values by reference, so that you can, for example, invoke member functions on the underlying value-object, including invoking virtual member functions when the underlying value-object is an instance of a subclass of the declared input type. TL_Systems do not and should not know anything about any other TL_Systems external to them, and they therefore must rely on an external mechanism to coordinate the advance of virtual time among all the systems in a given process. Similarly TL_Systems in general do not and should not know anything about external TimeLike processes (aka “TL_Things”), with the optional sole exception of the special case of a TL_NestedVirtualUniverse, which needs to know about the top-level TL_Things that belong to that nested virtual universe. OTOH, each “TL_Thing” does need to be able to coordinate the advance of virtual time among all the systems contained within it, and in general it does need to know about other TL_Things, namely those TL_Things with which it interacts via messages sent and received. Therefore, in certain embodiments, two different classes exist, TL_System and TL_Thing (which is derived from TL_System) to implement the base classes for all intra-process and inter-process layer components respectively.

A skilled artisan will appreciate that software, including the software to implement the TimeLike system itself, will need to change over time. Therefore “version control” can be incorporated into the architecture, to allow for the possibility that the “same” TL_Thing, e.g., the top-level container, may be implemented by different versions of software at different times over the course of its existence. To support this, a mechanism is provided, very much analogous to the TimeLike “variables”, e.g., system inputs and outputs, that are already used in TimeLike's intra-process component layer, but in this case a way to access it can be provided from anywhere across a large network, namely the IoT. The value-type for that variable may change over time, at least in the sense of one version of a class replacing an older version, even if the class-name remains the same.

For example, in some embodiments a “TL_Thing” is the “things” the TimeLike Visual Editor (TVE) can be used to edit; each TVE edit window presents an interactive view of one TL_Thing. Each TL_Thing contains a well-defined single-rooted containership hierarchy made up of TL_Objects, where TL_Object is the common base class for all TimeLike objects, including TL_System, which in turn is the base class for all the subclasses used to implement different kinds of TimeLike systems, and TL_Variable, the base class for TL_Input, TL_Outputs, and various other kinds of TimeLike variables further detailed herein. The class TL_Thing will itself be derived from TL_System, and it's role will be similar in most ways to that played by the existing class TL_Peer, with one significant difference: The class TL_Peer includes the assumption that it would sit at the top of the TL_Object hierarchy within a given TimeLike process, but that will not be the case for TL_Thing, Instead, although the TL_Thing object in each TL_Thing process plays the central role within that process, in general it will NOT sit at the top of the TL_Object containership hierarchy. Instead, the TL_Object hierarchy inside a given TL_Thing process should be thought of as defining the “world model” for that TL_Thing, and, just as a human's own mental models of the world contain both things that are parts of them, (e.g. arms and legs), and other things which are not part of them, but rather exist outside of them, in the environment; that will also be the case for the world models that exist inside TL_Thing processes.

In an embodiment, whenever a new “System Design” is created, it automatically creates a “default study”, where the default study just sits one level up in the containership hierarchy from the System Design itself, and it is used to define the context in which the given System Design exists, i.e., its environment. In such an embodiment the default study for a given System Design, can be accessed by opening an edit window looking at that System Design, and then, in the block diagram edit pane, double-clicking on whitespace, to ascend to the level of the default study. By default, the default study will contain just a single subsystem the System Design itself (but seen from the outside). However other systems can be dropped into that edit window, and connected to the System Designobject, using them to define the system design's external environment.

All TL_Things exist within some “virtual universe”, and each TL_Thing within a given “virtual universe”, and each TimeLike virtual universe is completely defined by the set of TL_Things that make it up. Each TL_Thing describes what exists and what is happening within some relatively localized spatial volume within that virtual universe. “Relatively localized” as used herein means that the physical extent of the TL_Thing needs to be kept small enough, relative to the time scales of interest for the systems and phenomena being modeled within that TL_Thing that only a single event scheduler/dispatcher and a single virtual time to model everything happening in that TL_Thing is necessary.

To understand why this is so, consider a TL_Thing being used to implement a real-world soft real-time system, e.g., coordinating how cars travel through city streets, so as to minimize travel time and energy usage, while avoiding collisions, clearing paths for emergency vehicles, etc. For that kind of an application, a few milliseconds of latency might be ok, but a few tenths of a second would definitely be too much. If 1 millisecond for round trip travel time is acceptable, a couple milliseconds for computations in between remains; that suggests that the geographic region assigned to any one traffic-managing TL_Thing should be no more than c*1 ms/2=3.0e8*1e-3/2=150 km. For physically large systems, like the solar system as a whole, which is on the order of light-days across, the whole system can be modeled using a single TL_Thing only if it is not included in that TL_ Thing phenomena happening on timescales less than a day or so. But that's no problem, because to model faster-changing phenomena, smaller, more localized TL_Things can be used. There is no prohibition against the spatial volumes described by different TL_Things overlapping one another.

It should be appreciated that every single TimeLike-based software system, large or small, no matter who creates it or owns it, will always exist at some well-defined location within a single, global, single-rooted containership/ownership hierarchy. For the top-most object, a very special TimeLike virtual universe, which will serve as TimeLike's internal representation of the actual physical universe we live in. All TL_Things which are used to implement real-world soft real-time systems will also be considered to exist within this same special virtual universe, as will every other TL_Thing that does any kind of job in the real world, whether it is a “soft real-time system” or not. This will include, for example, TL_Things that serve as a the top level TL_Thing for a given user's account, the TL_Things that will serve as the top-level things on different computers (or in different software containers), the TL_Things that will manage individual TimeLike directories (libraries and work directories), and so on.

The only TL_Things that will NOT be considered to exist within that one special virtual universe that represents the real universe will be those used in simulations. Each individual simulation “run” takes place within its own “nested virtual universe”, with its own virtual time and space. For example, for a parameter study based on a given system design, which might involve performing hundreds or thousands of simulation runs, a new virtual universe is created for each run. That sounds like it might be expensive, but it isn't; an empty virtual universes is a very lightweight object; it's the TL_Things that inside of it that use up computational resources, but those are precisely the things necessary to generate the desired results.

Accordingly, it is perfectly allowable to nest one nested virtual universe inside another—this just amounts to doing a simulation within a larger simulation. This would be useful for example when modeling autonomous cyber-physical systems or systems that used model-based reasoning in their decision-making, including cases where their internal models may include models of other autonomous systems that also use model-based reasoning, and so forth.

In TimeLike-writ-large, every kind of persistent software object will be implemented by some kind of TL_Thing (i.e., a subclass of TL_Thing). Unlike TL_System, which is designed to serve as the common base class for any number of different kinds of software components, in the case of TL_Thing, a new subclass can be introduced only when it is strictly necessary, and only a designated administrator can be allowed to create subclasses of TL_Thing, because it is going to be crucial to ensure that this set of classes are compatible.

In particular, in order to ensure that TimeLike can simulate anything, including cyber-physical or cybernetic systems that incorporate TimeLike-based soft real-time systems and/or model-based decision-making inside of them, it is essential to be able to copy and paste any subhierarchy within the overall TimeLike containership hierarchy from one place to another within the overall hierarchy. This includes user accounts, libraries, work directories, system designs, studies, composite systems, atomic systems, whatever. To make this work, it is necessary to be able to create whole new “computers” on the fly; this is made possible only by the use of software containers (specifically Kubernetes StatefulSets) and scalable Kubernetes clusters.

When copying a TL_System from one TL_Thing to another, it may also be necessary to copy over all of its pending events, and ensure that they will all arrive with the correct virtual time delays, regardless of any difference in virtual time between the two systems, because a system's pending events are part of its internal state. In an embodiment the initial location, orientation, and velocity of the TL_System within the new TL_Thing can be specified, relative to some reference frame defined within the scene graph for the new TL_Thing. (Unlike the translational velocity, the angular velocity should carry over unchanged, because that too is part of the system's internal state-that's because the laws of physics expressed in a given reference frame are unaffected by translational velocity, but they are affected by rotational velocity). This illustrates the need for integrated support for keeping track of 3D geometry and motion within TimeLike.

When a copy/paste of a real-world cyber-physical or cybernetic or cybernetic system into a nested virtual universe is attempted, all the software components are copied over directly, as well as the software containers they run on. As such a model of the communication network linking different devices, including latencies and any less-than-perfectly reliable connections can be created, provided the real world network was instrumented so as to gather that data. It I not possible to copy/paste actual hardware components; instead, the system can replace each hardware component with a corresponding “digital twin”, just for that one component, with the proviso that the only information used to initialize that digital twin is whatever run-time accessible state information the given hardware component provides.

What about a copy/paste of a TimeLike model of a or cybernetic system from a nested virtual universe back into the top-level virtual universe, the special one that represents the real universe we live in. A digital twin can't be copy pasted into the real universe and expect a corresponding hardware component to somehow magically appear. However, if a TimeLike model was created in the first place by copy/pasting a real world CPS (or cybernetic system) into the nested virtual universe, then the physical component corresponding to that digital twin should already exist, so it doesn't need to be copied.

In order to reliably keep track of exactly which real world hardware component a given digital twin represents, each such hardware component is assigned a “universally unique identifier”, or UUID, and that exact same UUID is assigned to the corresponding digital twin in the nested virtual universe. A UUID only needs to be “universally unique” within a given virtual universe; there is no reason two objects in different virtual universes can't have the same UUID, and in fact this provides a very natural way to verify that they are indeed both meant to represent the “same” object.

Of course, it may be the case that after doing a bunch of model-based design optimization, one or more new hardware components should be added to the given CPS, in order to improve its performance. In such cases the model can be extended to include the real world manufacturing and logistics systems needed to create the desired components, deliver/deploy them to the locations (including orbits) desired, and put them into the desired initial state. In general, the model also can include the financial transaction involved. Once the model is extended to include all of that stuff, the only thing that needs to be copy/pasted from the modeled system to the real world system are software/data only. In this case, the “paste” can trigger a real world financial transaction, and contract execution, and that will set the wheels in motion that will, over time, cause the desired new component to be manufactured/delivered/deployed, and hooked into the existing cps. In certain embodiment, built-in support for e-commerce, digital signatures, recording contracts, and security can be integrated in the platform.

TimeLike systems, everywhere, will always form a well-defined single-rooted part-of hierarchy. In an embodiment, the ontogeny of the disclosed system-of-TimeLike-systems can be a precisely defined overall pattern, used to eventually form a fully formed model. In the case of TimeLike, the special topmost TL_Thing, will always sit at the top of that well-defined single-rooted part-of hierarchy. Actually, to be more precise, it can actually have a time-series of topmost TL_Things, so that new functionality can be added and/or design and implementation changes can be included over time, each of them called, in succession, “TimeLike Systems”, where they could be distinguishable with a version number or timestamp, and each time a new one is added, it would become the container of the previous one).

Apart from that one special topmost TL_Thing, all other TL_Things can only be created by a previously existing TL_Thing, and they are created as parts-of the TL_Thing that created them. Under certain circumstances TL_Things are allowed to be moved from one place to another within the overall part-of hierarchy, but both before and after the move they will occupy some well-defined location within the hierarchy, and during the pendency of the move they will be in serialized form, so their internal state will be frozen.

Aspects of subclasses of TL_Thing, and where TL_Things reside are further detailed herein. At a minimum the set of defined subclasses of TL_Thing should include class to implement (a) the one special topmost TL_Thing, (b) the topmost TL_Thing for each user account, (c) the topmost TL_Thing for each software container (each of which, for now, can be a Kubernetes StatefulSet running Linux), (d) the topmost TL_Thing for each TimeLike Directory within a given Stateful set (includes both Libraries and WorkDirectories, each of which can be a subclass of TL_Directory), (e) TL_SystemDesign, (f) TL_SystemStudy, and (g) the topmost TL_Thing for a scalable Kubernetes cluster.

Every TL_Thing resides in some TL_Directory, either a TL_Library or a TL_WorkDirectory, which also contains all of the source code and object code needed to implement the given TL_Thing and all of its subsystems, apart from the code contained either in TL_Libraries referenced by the given TL_Directory, or in the TimeLike kernel. For reference if a given TL_Thing “resides in” a given TL_Directory, that means (a) when the given TL_Thing is in a “passive” state, the serialized data defining its current state is stored within that directory, and (b) when another TL_Thing needs to send it a message, it's handle, aka its “dotted name”, places it somewhere under that TL_Directory within the global TimeLike part-of hierarchy.

Furthermore, coordinating virtual time among TL_Things within a vU, while allowing different “governors” to be applied to one or more of those TL_Things, sometimes requires strict determinism, and sometimes that requirement can be relaxed. Replay can work in all such cases. Additionally, TL_Things in different vUs can be allowed to reside within the same directory. In certain embodiments, directory nesting can parallel the vU nesting.

As a further example, systems like Sum and Quotient, which don't have any notion of position or extent of their own can be considered to be point-like objects located at the origin of the reference frame associated with the composite system they are part of. If that composite system also has no notion of position or extent, both it and its subsystems can be considered to be point-like objects located at the origin of the reference frame associated with the composite system *it* is part of. Ultimately, all TL_Sysems exist within some TL_Thing, and each TL_Thing always has a well-defined location, within some particular virtual universe. There is one special “top-level” virtual universe, which acts as TimeLike's internal representation of the real universe we live in, and all the TL_Things that are part of that one special top-level virtual universe represent real-world objects, which exist at specific real world locations.

Apart from that one special one, all other virtual universes are nested inside some other virtual universe—for example the top-one, or possibly some other nested virtual universe—and all nested virtual universes are used for running simulations. All TL_Things within nested virtual universe have well-defined locations within that virtual universe.

As an example, consider the case of TL_Things that exist within the top-level virtual universe first; how does the system decide where a given TL_Thing is located? To begin, consider the very simplest case, an empty TL_Thing which has just been created; where is it located? It is located on the computer system where it is running (when active) or where its state is stored (when passive) at any given time. In most cases, the key is to be able to associate it with a particular hardware device, so that, if that device moves, the system knows that it is carrying the given TL_Thing with it. And all of the instance of Sum, Quotient, etc. that it contains are resident on that same device.

The assignment of some particular physical extent to a given TL_Thing depends on two inter-related criteria: (1) what is the particular role assigned the given TL_Thing and (2) what other TL_Things are considered to be parts of the given TL_Thing. For example, supposed there is a localized or cybernetic system such as a car, a ship, or a building, and the goal is to assign one particular TL_Thing to act as a software interface to that entire or cybernetic system; in that case the point like “brain” of the TL_Thing would still be located on the particular computer where it is running, but the physical extent of its “body” would correspond to the physical extent of that or cybernetic system. Furthermore, if that or cybernetic system contains other, smaller TL_Things, acting as subsystems within it, each of those TL_Things would be considered part of the TL_Thing that represents the overall or cybernetic system. Each of those can have their own physical extent, defined similarly, and the physical extent of the overall TL_Thing can always contain the physical extent of all the TL_Things that are parts of it.

One aspect of the disclosed embodiments is that for variables that are functions of position as well as time, each TL_Variable will represent a function of position as well as time. Furthermore, there are two different kinds of “position” that are relevant: (1) position in x-y-z space (defined with respect to some specified reference frame) and (2) position within the TimeLike part-of the containership hierarchy.

For example, consider variables like “pressure” or “density” or “temperature”, which can be defined at any point in space; to request the value of such a variable at a given point in space, (x-y-z; refframe) at a given moment in time, instead of using get(t), it is necessary to use get(t, x-y-z, refframe). But now suppose a TimeLike model includes a body of water and a submarine, somewhere inside that body of water. Here is how the containership hierarchy comes into play: If, inside code that is executing at the scope of the body of water, you call pressure. get(now(), x0-y0-z0), and the value of x0 -y0 -z0 happens to correspond to a point inside the submarine, the value that should be returned is that of the ambient pressure of the body of water at that location, NOT the pressure inside the submarine. However, if you make that same call inside code that is executing at the scope of the submarine, it should return the ambient pressure at that point within the submarine.

Another aspect of the disclosed embodiments includes “environment variables”/ “locals”/“implicit inputs and outputs.” When building models of complex systems, it sometimes happens that there are certain kinds of information that need to be accessible from almost anywhere within a big, complicated model, but it doesn't make sense, to clutter up the input-output interfaces of all systems at every level of the hierarchy, many of which may make no use of that info, just so that those that do can have access. To deal with such situations, “environment variables” can be used. They are a subclass of TL_Variable, where the idea is that they can be used define an envVar at any point in the TimeLike part of the hierarchy, by giving it a name, a type, and a value, and then it can be visible to all parts of the hierarchy below the point where it was defined.

Also, once an envVar has been defined, its value can be overridden at any point in the part of the hierarchy where it was visible, and then that new value is what would be seen in all parts of the hierarchy below the point where you overrode the previous value. Note that for any system that makes use of a particular envVar, that envVar would constitute a part of its external interface, and that needs to properly be taken into account. For example, if you copy/paste such a system from one context to another, if the new context lacks an envVar that the newly copied system requires, that's an error condition, which can be detected, to warn the user about, and to give them an opportunity to fix it.

An envVar, as previously described, acts a lot like an input, except that, (a) instead of needing to be connected locally, it can be resolved by recursive upward search, and (b) typically it is preferrable not to make it as conspicuous a part of the given system's “official” interface as inputs and outputs. This suggests combining the two, and allowing inputs, if left unconnected, and if no default value has been provided, to be resolved via a recursive search, and also to allow some inputs to be “hidden” by default. That's one possible design solution, but others may also be used.

Another embodiment can include combining the notion of an envVar with that of a “local”, i.e., an instance of TL_Local<T>. In the present embodiments, a local defined inside one system is not visible to any other systems, including its subsystems. However, if the locals are chosen to be system visible to its subsystems, they then play the same role as envVars.

Another related aspect disclosed embodiments herein is the idea of “implicit” outputs, i.e., outputs which provide access to information about a system that is well-defined, but which is not directly related to the intended purpose of the system, so, once again, it doesn't, in my opinion, make sense to clutter up its “official” interface with extra outputs just to provide access to that information. For example, for almost any system, it is meaningful, and sometimes of interest, to ask what its mass is, or its location, orientation, velocity, angular velocity, and so forth, but, precisely because it makes sense to want to be able to ask those questions of any system, it doesn't make sense to require the designer of a particular system design to have to declare them as part of his system's interface, or to have them show up in the GUI when its outputs are unfolded. Thus, one aspect would be to provide access to these kinds of things as part of the standard interface defined by the class TL_System.

It should be appreciated that TL_Systems can ask each other for values (basically, pull), and provide values (push), and some other things. Each TL_Thing (i.e., TimeLike process, with persistence) gets its own UUID, and is considered to be part-of some particular TimeLike Virtual Universe, either the one special top-level vU which serves as TL's internal representation of the real universe we live in, or a “nested vU”, used for simulation. Only one TL_Thing in any given vU should have a given UUID, however there are cases where two or more TL_Things in different vU will share the same UUID; this indicates that they represent the same (real or hypothetical) real world object.

Aspects of the process model are disclosed herein. At least for a “plain vanilla” TL_Thing, one main execution thread can be used, plus one auxiliary thread to listen for messages coming in from other processes and stick them into the appropriate place in a queue of messages to be processed. This design is intended to ensure deterministic and repeatable execution, where the “repeatable” part includes storing the external messages that arrived and “playing them back” in the exact right sequence.

An alternative embodiment includes allowing the main execution logic to be split up into multiple threads, to split the work up among multiple processors, to ensure that that would not violate determinism, requirements related to thread safety that “print through” to nontrivial requirements component implementers. It may be useful to provide a multi-threaded variety of a TL_Thing, within which you could only use guaranteed-to-be-thread-safe TL_Systems. In such an embodiment, a menu of maybe 2-3 models can be provided.

In general, the only other TL_Systems a given TL_System should know anything about are those it directly contains as subsystems. It should know that it has a containing system (except for the very topmost one), but it shouldn't know anything specific about it. Ordinarily it should interact with systems external to it only by means of its inputs and outputs (and optionally envVars).

In an exemplary instance, suppose it is necessary to implement a big, complicated, globally distributed cyber-physical system, or cybernetic system. One important design decision is where to put the decision-making logic for all of the many localized “Things” that make up that system of systems. In such cases in an exemplary embodiment, the general policy can be to keep it as local as possible, but no ‘localer’.” The basic aspect is that, when feasible, the sensors, actuators, and decision-making logic required to accomplish a given task should all be collocated, ideally on the same physical device, and when that's not feasible, as close as possible in terms of both physical space and network connectivity. This approach allows the system to minimize (1) latencies associated with communication delays, (2) the total network traffic, especially for non-local “long-haul” lines, and thus the required capacity and cost of the communications network, (3) the vulnerability of the system to unreliable or intermittent connectivity, and (4) the vulnerability of the system to various forms of deliberate attack, e.g., cyberwarfare.

As disclosed, this leads to a hierarchical system architectures, where at each level, in a well-designed system, each local piece of decision-making logic (or “agent”) always has a current set of “marching orders” telling it what to do, using the “actuators” available to it, based on the information available from the “sensors: connected to it, including when and what it needs to report to its “superior”, as well as what info to send and receive from its “peers”. At higher levels in the hierarchy, each agent uses its subordinate agents to act, in effect, as both its “sensors” and “actuators”, and when needed the superior can also provide its subordinates with needed information not directly accessible to them—e.g., “lookout for such and such—it's headed your way!”-and/or to change their “marching orders”. In TimeLike, any given system's “marching orders”, i.e., the logic that tells it what command signals to send to its actuators based on the signals it receives from its sensors can be implemented as a TL block diagram, and any required changes to a systems marching orders, large or small, can be made by its superior by sending it serialized messages, containing sets of TL: API commands. Using this same basic approach, in an embodiment TimeLike can be used to design, implement, operate, and maintain complex distributed systems of or cybernetic systems—sometimes incorporating “wetware” decision-making elements—to carry out any and all of the tasks that humans and human organizations currently do, or may need to do in the future, while bringing in much-improved capabilities for model-based decision-making, which can take advantage of the fact the all the or cybernetic systems themselves—with the exception of the wetware elements, can and will provide accurate predictive computer models of themselves, which can be used to explore alternative-spaces, in the attempt to achieve various human-defined objectives.

Another aspect of the embodiments is the use of superposable models, using models “by reference”, revision tracking, etc. To review, in TimeLike a “‘virtual universe” can “contain”, i.e., be made up of, any number of TL::Things, where each TL::Thing resides in its own process, when active (i.e., when its state is changing), and also its complete state can be saved in a serialized form, e.g., a file or directory, when not active. In some case these TL::Things may all reside on the same computer system, e.g., to support use cases where it is necessary to be able to use TimeLike when offline, or with an unreliable or low bandwidth connection. In other cases, the TL_Things making up a given virtual universe may be distributed across any number of computers connected in a network. Each TL:Thing contains a “causal” (i.e. using TimeLike mechanisms and complying with best practices, designed to ensure that the time evolution of the TL::Thing's state with respect to virtual time obeys causality in the same sense real world systems to, due to the laws of physics) software system (generally either a real-world software system which may include software interfaces to hardware components, or a computer model of some real world causal system) comprise a hierarchical structure made up of interacting TL::Systems. Each TL::Thing, at any given moment has some well-defined location and spatial extent, or “bounding volumes” with respect to the overall “scene graph” associated with its virtual universe, and, over time, it follows some well-defined trajectory through its virtual universe. In general, the bounding volumes of different TL::Things within the same virtual universe can and often will overlap one another in space; if this seems strange, bear in mind that many systems of interest, e.g., the solar system, or a satellite network, may be sparsely spread out throughout their bounding volumes. Now, within each TL:Thing, the hierarchical structure of TL:Systems contains one special TL:System with represents the TL_Thing itself, and in general this “self-model” will not sit at the top of the containership hierarchy. Instead, the containership hierarchy defines the TL:Thing's “world model”, and everything in that hierarchy which sits outside of its self-model constitutes the TL::Thing's internal model of its surrounding environment, while everything that sits inside its self-model is considered to be part-of the TL::Thing itself. Now, in some cases a TL:Thing may not need to know much at all about its surrounding environment, and furthermore, it will often be important, from the standpoint of efficiency, affordability, and minimizing computational requirements, to include nothing more in its environment model than it absolutely needs to know. (For example, a TL::Thing tasked with running a smart home probably doesn't need to know about exoplanets.) But in other cases, including the very important use case where it is desireable to use TimeLike to greatly extend and enhance the kinds of world models that can be constructed, the TL:Things will need to have extraordinarily rich world models.

It is noteworthy that each individual TL::Thing can be a single computer process, which means that there are practical limits on how large it can get (in terms of memory size) and how much computation it can do; this is especially true in the case of TL::Things designed to carry out tasks in the real world (aka “reality0”), which are supposed to keep themselves closely synched to wall clock time. That means within any one TL::Thing it is only possible to “see” just so much of the overall model/system at any one time.

Note, where a single edit window (i.e., a single top level “tab” in the current TVE) is attached to a single TimeLike process at any given time, this will also make sense for other sorts of “views ”of TL::Things, e.g., in AR or VR. That said, this system is configured to make it easy for users to navigate their way around coupled systems of TL::Things in as seamless a fashion as possible. For example, inside the block diagram editor, this system is configured so that a double click on a TL::ThingRep, i.e., a special kind of subsystem designed to serve as a local representation, within one TL::Thing, of some other TL::Thing that it knows about, that can automatically route into that other TL::Thing.

Aspects further include “superposable” models, using models “by reference”, and “revision tracking”. Suppose it is necessary to create a TimeLike model of some hypothetical system, and to embed it within an existing model of the real world.

In further embodiments, for TimeLike users modeling real or hypothetical systems meant to exist within the real world (presumably by far the most common use case), all of those users can share the exact same read-only world model. Thus, the online cloud-based shared environment model is as complete as possible. It can include detailed models of every part of the Earth's entire biosphere and everything happening within it, including all human activity—in both the present and the past—and artifacts, ecosystems, weather, and climate, near-earth space, the solar system, other stars and galaxies.

As used herein the term “superposable” is meant to be understood as follows. Starting with an empty TL::Thing which can then be imported—by reference—to existing models. “Importing an existing model by reference”, means that the model exists as a TL:Thing somewhere on the same computer network, within the local TL::Thing, a local representation of the remote TL::Thing, i.e., a TL::ThingRep is constructed, and a communications link between the two is established. (For this application assume that this comm link permits only read-only operations on the remote TL::Thing). One of the functions that a TL::ThingRep will need to support is to describe the physical appearance of the TL:Thing it represents, by providing, on demand, an up-to-date 3D model of it, suitable for use in scene rendering. Thus, as existing TL:Things are import-ed by-reference into the local TL:Thing, inside the local TL:Thing using AR or VR gear, the scene will be getting more and more detailed and complicated. The user can thus select what existing TL::Things need to be imported, and when, and that will depend on the application, and in general may change quite a bit over time. Note that this means an “un-import” existing models' option must be available. When an import-by-reference of two or more models into a given TL::Thing occurs, they are “superposed”, meaning they are added into the model of the environment, and they don't interact with one another in any way, because their actual behavior, as opposed to their appearance is defined by the remote TL::Things imported-by-reference, and, by assumption in this example, only read-only access to them is available.

Thus, using AR gear, as an import-by-reference operation of one TL::Thing after another is completed, each imported TL:Thing may include any number of visible 3D objects, distributed over an arbitrarily large-but finite-volume. The bounding volumes of different TL:Things may overlap one another in space, and in some cases the visible objects within them may likewise overlap. In such cases, a reasonable default is to show (in AR/VR) both objects, overlapping, even if that looks very strange. In other cases, however, where the 3D representations of two different TL::Things overlap one another, one should override the other. For example, if one TL:Thing provides a model of the ocean, as it would appear with no ships moving across it, and another model adds ships, which displace water and produce wakes, the latter should override the former. The resolution is to allow a TL::Thing that imports-by-reference a read-only representation existing TL:Thing, the first TL:Thing should be able to apply mutating operations to that local representation, which would have no effect on the refenced TL:Thing. For example, the TL:Thing that added the ships on top of the ship-less ocean would import the model of the ship-less ocean as-is, and then apply incremental “revisions” to the local representation, including the 3D model, to add the ships and their wakes and displace the water that would be displaced. Other sorts of “revisions” include changing the position, orientation, velocity, etc., of the local reps of imported TL:Things, e.g., to assemble new hypothetical scenes from already-modeled scene elements, and/or displacing them temporally, so that you could, for example, change the weather in a given model by playing back recorded weather from some other day.

For certain situations a model has to be built from scratch, i.e., from first principles, then verify and validate it, and then, if possible, develop a much faster-running surrogate that can be used in place of the slower-running first-principals model.

In certain embodiments, minimalist versions of the most-core classes in the TimeLike namespace—namely Object, Variable, Variable<T>, Input, Input<T>, Output<T>, and System can be used. For TL::Object, its “most-core” functionality boils down to defining the containership hierarchy and providing a unique “dotted-name” identifier for each object. That requires just these three data members: char* name; TL::Object* container; std::vector<TL::Object*>containees; etc. For minimalist versions of Variable, Variable, Variable<T>, Input, Input<T>, and Output<T>, even though, the system can support both “mutable” (as opposed to “const”) and “multi” (as opposed to single-valued) versions. In certain embodiments the system can implement all the required functionality other than (a) interaction with systems, and (b) typed access, in the non-templatized version of the class Variable. This will include making and breaking connections, keeping track of what's connected to what, and propagating notices of discrete changes forward, and in-line warnings of access requests backward. Aspects can include keeping track of what used to be connected to what, in order to support recallability.

The only thing the classes Input and Output can add to Variable (from which they will be derived) is logic related to interacting with systems. And the only thing the templatized classes Variable<T>, Input<T>, and Output<T>can add to their respective non-templatized counterparts is typed access assumed by the given Variable at various moments in virtual time. To provide typed read-only access to the value of a given Variable with value-type T, a single member function “const T& getValue(Time t)” can be provided. The name “getValue()” rather than the shorter “get()”, is that it can reflect a clear distinction between a Variable, which represents an object-valued function of time, and its instantaneous value at some one moment in time.

In an exemplary embodiment of a minimalist version of the system, system designs with various commonly occurring behaviors, can include several representative use cases.

Examples Include:

1) the “pure function”/stateless case gives an easy way to “wrap” any pure function, where the current values of the outputs depend only on the current values of the inputs. 2) wrapping a stateful third-party software component: these will generally have purely discrete behavior (no continuous-time behavior) and will change their internal state and outputs only in response to either (a) discrete changes to their inputs, and/or (b) in response to their own internally scheduled discrete events. Also, I in most cases their outputs would be serializable, implying that a complete time history of any output can be preserved, for recallability purposes, simply by recording a series of time-value pair; 3) A continuous-time integrator (for a real-valued scalar or vector); 4) An algebraic constraint; 5) A system with behavior defines by a set of ODEs; 5) A system with behavior defines by a set of DAEs; 6) A system with behavior defines by a set of fixed time-step difference equations; 7) A fixed delay y(t)=u(t-fixed_delay); 8) A variable delay y(t)=u(t-variable_delay); 9) A rotational velocity-to-orientation (expressed as quaternion) integrator.

In certain embodiments, reasonable default values for inputs can be used, since their value is expected to vary over time anyway, but possibly not for some parameters, especially since parameters' values are looked at only once, at the moment in virtual time we construct an instance of a system design, and if they are not set correctly at that moment, there are no “do-overs”. Also, a reasonable default value for an input, or, more generally, any TL::Variable, that could solve one of the main challenges of implementing support for recallability, namely dealing with cases where the value of a given TL::Variable at a time before that TL:Variable was constructed is required. Thus, a requirement can be imposed that any TL:Variable must have some well-defined value for all times prior to the construction of that TL::Variable, and see if that works out.

Generally, the system can mechanically turn an input of say double, into a little struct of {double d; bool bUnset;} so that any case where there's a truly unset input condition that we must be aware of, we can make the default value [0.0, true] (with 0.0 not mattering. For example, a System with three inputs a b c. Say the module simply implements if (a) then output =b else output =c. If a is undefined, but b and c are the same, output (say) b. If a is a constant 1 or true, then it doesn't matter if c is undefined; again output b.

In an embodiment, TimeLike can be configured to establish who can set an input equal to some complicated expression involving functions of other TL::Variables. This can be implemented using the existing “connect only to a variable” mechanism. The basic idea is that an expression involving TL:Variable would be automatically mapped into a “persistent expression tree” made up of TL:Systems, which would be used to evaluate the expression as and when needed, and also take care of the signaling required for connection-driven interaction. For example, if you defined the value of a TL:Variable v1 to be equal to “v2+v3” (also TL_Variables), that could be implemented as follows:
in C++ you could write the following line: v1<<=v2+v3;2. This can override the operator TL::Variable::<<=() to mean, in effect “attach to the result of evaluating the RHS”, and the operator TL::Variable::+() to mean create an instance of a “Summer”, a TL: system that takes two inputs and produces one output, and connect the two variables its operating upon to its two inputs. For systems that are used in this manner, as expressions or subexpressions, the RHS can evaluate to a reference to the output of that Summer. Also, reference counting can be used so that the Summer can be safely deleted.

In an embodiment, the systems can be thought of as an operating system for networked systems-of-(distributed or cybernetic systems) that exist and interact within a very large, very complex, very heterogeneous dynamic 3D+time physical/biological environment, namely the biosphere of the Earth, plus near-Earth space and any other terrestrial or extraterrestrial system. All of those systems will in general be coupled to one another, directly or indirectly, via a super-high-bandwidth communications network with maximum delays of a fraction of a second. The system can comprise a distributed operating system, over a collection of independent software, networked, communicating, and physically separate computational nodes. They handle jobs which are serviced by multiple CPUs. Each individual node holds a specific software subset of the global aggregate operating system. Each subset is a composite of two distinct service provisioners. The first is a ubiquitous minimal kernel, or microkernel, that directly controls that node's hardware. Second is a higher-level collection of system management components that coordinate the node's individual and collaborative activities. These components abstract microkernel functions and support user applications.

In further embodiments, it can comprise an artificially intelligent distributed operating system employing a combination of model-based and “model-free” (so-called) AI/ML approaches. Model-free AI/ML, applications can be (1) constructing models for systems without models for, (2) iteratively improving those models, as more data becomes available, (3) constructing faster-running surrogate models that can be used in place of slower running higher-fidelity models, e.g. for model-based optimization and/or parameter space exploration, and (4) iteratively improving those models, by selectively performing additional simulation runs of the higher-fidelity model in order to better sample regions where either (a) the outputs of interest are more rapidly changing, or else (b) greater accuracy is needed.

Aspects of the software associated with the disclosed systems and methods are provided herein. Aspects include defining the C++ class hierarchy that will provide all of the essential functionality. API(s) can be provided to give access to that functionality. A GUI may also be provided.

Much of the class hierarchy retains the same basic structure:
TL_Object
TL_Variable
TL_Input
TL_Input<T>
TL_Output
TL_Output<T>
TL_Local
TL_Local<T>
TL_System

“TL_Peer” becomes “TL_Thing”, with changes, includes event scheduling and dispatch and interactions with outside world, and that is it with regard to w the minimalist TimeLike kernel. All system designs, studies, etc. can be moved into a separate project that references the kernel, as well as anything related to the new inter-process component layer.

Another aspect of the embodiments is an integrated-continuous-time-solver. this can include integrating a continuous-time solver into a component-based simulation framework such as TimeLike,

In certain embodiments, the solvers can assume that all the continuous-time states to be integrated for the entire continuously-coupled system must always be packed into a single contiguous vector, and, in the case of an ODE solver, it's the same for the state derivatives, and the two vectors, the states and the derivatives, are the same length, and in the same order. In an embodiment, the way the ODE solvers work is that they make multiple calls to the user-supplied function that computes the state derivatives based on a given assumed state, and then they use the results of those calls (one state derivative vector per call) in a weighted sum, to create a new guessed at state. Fixed-step integrators, e.g., RK4, do these steps in a fixed pattern each time step, with no convergence test; variable step integrators add a convergence test. For a DAE-solver, they work much the same way, except that, instead of vectors of state derivatives, you wind up working with vectors of “residuals”.

ODEs are a special case of DAEs, and working with DAEs allows the addition of algebraic constraints. In certain embodiments, users can specify their components behaviors in terms of ODEs rather than DAEs if they find that more natural, and then the system can convert the ODE-style representation into a DAE-style representation.

The system implementers don't have to keep track of where the particular states and state derivatives (or residuals) pertinent to their particular system happen to be within the giant overall vector, and in fact don't have access to the rest of that giant vector at all. Also, even within a given system, the implementer doesn't have to pack all their state variables into a single common vector; a much more natural representation would be to have some number of distinct local variables to represent different aspects of the system's continuous time state—e.g., position, velocity, orientation, and angular_velocity—where each of those variables may be scalars, vectors, or arrays, as appropriate. Therefore, the system will let system implementers declare and work with however many different state variables they needed, giving each a descriptive name within their own code, while at the same time correctly mapping each such state variable into a well-defined continuous set of elements in the overall state and residual(or derivative) vectors.

This involves two new classes, TL_DaeState and TL_OdeState, each of which can be declared and used as if it were a normal n-dimensional array (with fixed dimensions) with a scalar state variable being just one special case. Internal to those classes, they hide the details of where exactly within the overall state and residual vectors each state variable is located.

The locations of the state variables can be ordered in the overall vector according to the order in which they are declared, with the first declared going first, the second, and so one. At the time of the declaration of each state variable, its number of dimensions is specified (0 to n) and number of elements per dimension, so that it knows how big a chunk of the overall state & residual vectors to reserve.

Each continuous-time TL System may need to override a virtual method, computeDaeResiduals() or computeOdeDerivates(), where it can compute its state residuals/derivatives based on its current assumed states. The class that implements the DAE solver can be a “friend” to TL_DaeState, so that it can update the state values prior to each call (and similarly for the ODE solver, which can just be a thin layer atop the DAE solver). This suggests that all TL system classes which use DAEs to define their internal time dependence can be derived from the same base class, TL_DaeSystem, with the virtual method computeDaeResiduals(). Similarly, all TL system classes which use ODEs to define their internal time dependence can be derived from the same base class, TL_OdeSystem, with the virtual method computeOdeDerivatives(), where TL_OdeSystem can be derived from TL_DaeSystem.

Two important concepts in TimeLike are “variables” and “systems”, implemented by instances of the classes TL_Variable and TL_System, respectively, or often, by subclasses of those two classes. In TimeLike, the term “variable” refers to an object-valued function of virtual time, whereby “object-valued”, means that the instantaneous value of the function at any given moment in virtual time is defined by the instantaneous state of some OOP object.

Another aspect of the embodiments is the integrated modeling of 3D geometry, motion, and mechanics. Each TimeLike process (i.e., each TL_Thing) will have its own “scene graph”—or “scene tree”, because that′ how scene graphs are typically structured. All but the leaves of the scene tree will comprise reference frames, each of which will be defined in terms of its parent frame. To transform just x-y-z coordinates between a frame and its parent, the information required is (a) the x-y-z offset between the two origins, and (b) quaternion defining the rotation that relates the orientation of the two frames.

However, the relative motion of the two frames may be of value to track, and it may be useful to model physical mechanics within any frame, taking into account whether it is an inertial frame or not. To do this, the velocity, angular velocity, acceleration, and angular acceleration relating the two frames can be tracked. Finally, in order to correctly account for the effects of gravity, the fact that only freely falling reference frames are truly inertial frames can be used. Even in that case, in general that is only strictly true in an infinitesimal neighborhood about the origin of the reference frame, because, in any physically realistic gravitational field (any field which is not perfectly uniform in both magnitude and direction), freely falling objects will not travel in straight lines with respect to one another. To take that into account, a few more items to keep track of include: tracking over time, of (a) the instantaneous acceleration, (b) angular velocity, and (c) angular acceleration relating each frame in the scene tree to an instantaneously aligned inertial frame—that gives all the information necessary to know how to do mechanics in the near neighborhood of each frame's origin. Second, in order to take into account, the fact that the local gravitational field is generally not going to be perfectly uniform in strength and direction, the field varies across the entire finite-sized neighborhood about the origin within which the system is able to do mechanics (the Clohessy-Wiltshire equations are the solution for one particular special case of this).

Another aspect of the disclosed embodiments is various features which, for example, make it possible to label input-output connections. A TimeLike component can be used for the specific purpose of computing a specific variable that is of interest e.g., “acceleration” or “velocity” but the name of that variable is in no way related to the name the TimeLike component assigns to its output, which is typically based just on the specific operation it performs, e.g., “quotient” or “integral”.

In certain embodiments, it is possible to delete library components. In certain embodiments, there is a delete function, but it can't work while TVE is running. However, it can be acceptable if it queued the deletion up to happen at shutdown. Other features include a feature to rename library components; a feature to export and import library components; a feature to allow people can share system designs; a feature to export and import data type definitions; a feature to add a string data type; a feature to edit from the UI values of type Vector<double>; a feature to add a documentation field to inputs and outputs so people unfamiliar with the system design can be sure of the meanings; a feature for validity checking at least for syntax to data value editing; a feature providing 3-D visualization (in an embodiment, Matlab ® can be used for this purpose. The TVE requires timelikemanager, so another feature includes the ability for TVE to communicate an error if it finds no timelikemanager running, In an embodiment, TL_Time.h, can include a constructor that takes type double for the time.

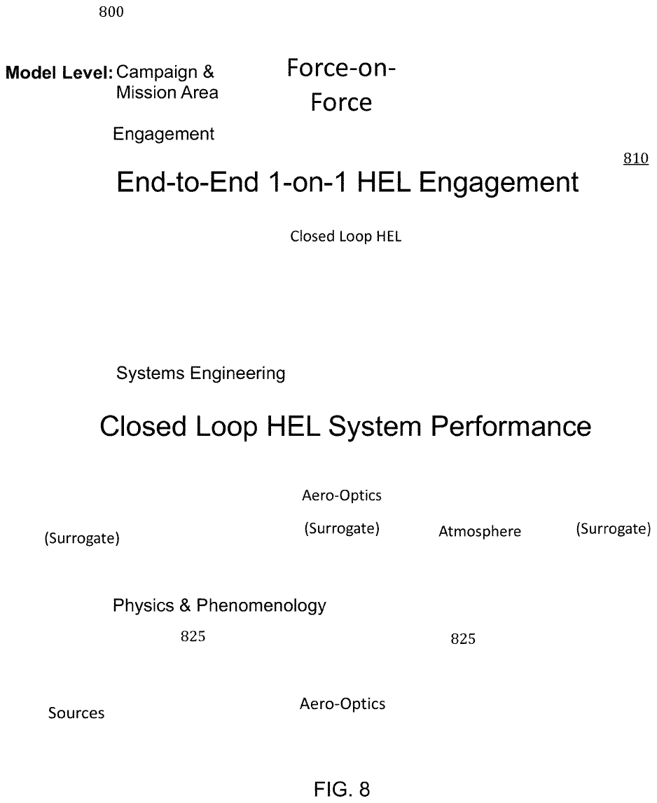

FIG. 8 illustrates an exemplary diagram of system levels and components 800 in accordance with the disclosed embodiments. It should be appreciated that the application illustrated in this figure is exemplary and similar system level architecture can be applied to other applications without departing form the disclosure herein.

As illustrated the levels can include a campaign & mission area 805, an engagement level 810, a system engineering level 815, and a physics and phenomenology level 820. Furthermore, this diagram 800 illustrates how surrogate models, i.e., simplified, lower fidelity faster-running models of systems or subsystems that for some purposes, e.g., parameter space exploration and model-based optimization, can sometimes be used in place of slower, higher fidelity models, in addition, the upward and downward-going pairs of arrows and boxes 825 indicate a two-way relationship between each pair composed of one higher fidelity and its corresponding surrogate model.

The nature of the relationship is exemplified in the following example. When, in the course of parameter space exploration or optimization, the surrogate model is asked to produce either: (a) simulation results for parts of the system's parameter space outside the region for which the surrogate model has been anchored to the high fidelity model; or (b) it is asked to produce results with a smaller estimated residual fitting error (as compared to the higher fidelity model) than its current estimated residual error in the specified region of its parameter space. To deal with this, an automated “harness” is provided, indicated by the box 825, which performs additional simulation runs with the high fidelity model, and uses those results to either (a) extend the region over which the surrogate model is anchored, and/or (b) reduce the estimated residual error in the specified region of its parameter space. Finally, as indicated in the diagram 800, these surrogate model+high fidelity model pairs can be used at any level of model fidelity—each separate level in the diagram indicates a different level of fidelity, where the higher you go in the pyramid, the lower the level of modeling fidelity, and vice versa.

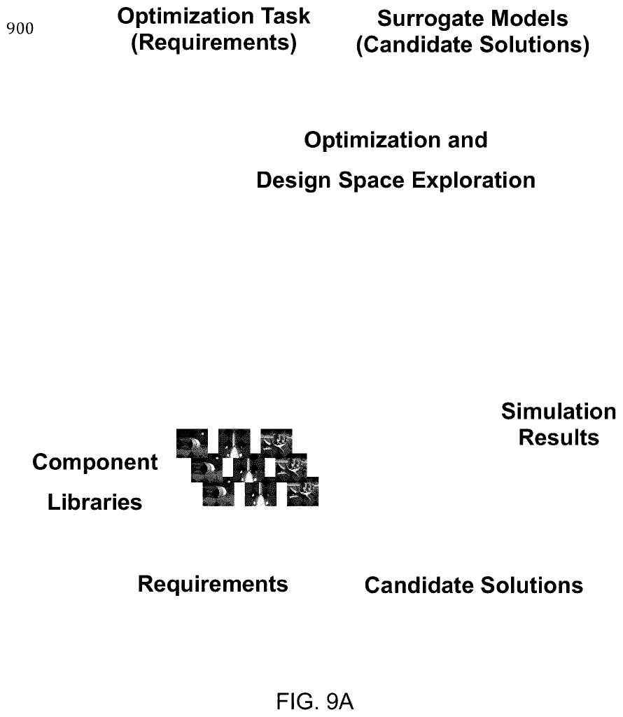

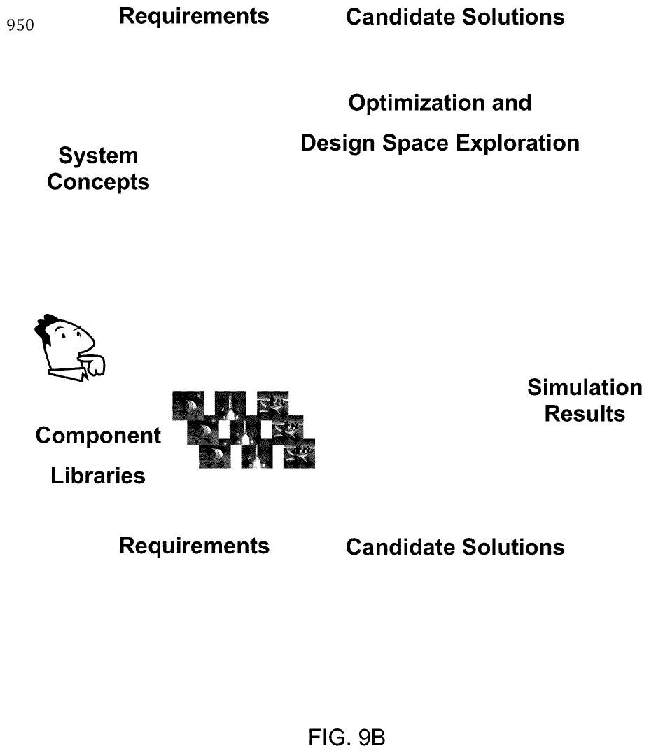

FIG. 9A illustrates aspects of implementation of the systems and methods as disclosed herein. In order to use a system, the problem to be addressed by the framework 900, the task 905 needs to be cast into the form of well-defined optimization tasks. A well-defined optimization task comprises a model of a system or subsystem and its environment; a specified region of the system's parameter space to be explored; a set of requirements and constraints; and one or more objective functions, with required accuracy for each. If the system model includes subsystems, optimization tasks for those can be created as well.

As illustrated by the follow chart 950 in FIG. 9B, component-based modeling enables an engineer to focus on one piece of an engineering problem at a time. Each engineer receives requirements (and constraints, etc.) from the next level up, and provides candidate solutions designed to meet those requirements. With a human in the loop, they can invent and refine their own system concepts. Each engineer also defines the requirements for the next level down, and receives candidate solutions in return.

Based on the foregoing, it can be appreciated that a number of embodiments, preferred and alternative, are disclosed herein. In an embodiment, a system comprises, a computer system further comprising: at least one processor; and a computer-usable medium embodying computer program code, the computer-usable medium capable of communicating with the at least one processor, the computer program code comprising instructions executable by the at least one processor and configured for: identifying a real-world cyber-physical system, generating a predictive digital twin of the real-world cyber-physical system, generating at least one additional predictive digital twin comprising a copy of the predicative digital twin of the real-world cyber-physical, simulating changes to the real-world cyber-physical system using the predictive digital twin(s), and uploading software-only components to the real-world cyber-physical system based on the results of the simulations. In an embodiment, generating a predictive digital twin of the real-world cyber-physical system further comprises automatically generating the predictive digital twin.

In an embodiment, automatically generating the predictive digital twin of the real-world cyber-physical system further comprises creating copies of software-only components of the real-world cyber-physical system. In an embodiment, automatically generating the predictive digital twin further comprises modeling at least one computer associated with the real-world cyber-physical system used to run the software-only components of the real-world cyber-physical system. In an embodiment, modeling computers associated with the real-world cyber-physical system comprises requisitioning a stateful container and putting the stateful container into a same state by copying all files from a given software container in the real-world cyber-physical system to the modeled computer in the predictive digital twin of the real-world cyber-physical system. In an embodiment, automatically generating the predictive digital twin of the real-world cyber-physical system further comprises generating a software model of each hardware component used in the real-world cyber physical system. In an embodiment, generating the software model of each hardware component used in the real-world cyber-physical system using run-time accessible state information from the real-world cyber physical system. In an embodiment, automatically generating the predictive digital twin of the real-world cyber-physical system further comprises modeling a communications network of the real-world cyber-physical system. In an embodiment, modeling a communications network of the real-world cyber-physical system further comprises artificially imposing limitations on corresponding communications links within the predictive digital twin. In an embodiment, simulating changes to the real-world cyber-physical system further comprises simulating perturbations to the cyber-physical system. In an embodiment, simulating changes to the real-world cyber-physical system further comprises simulating different operating conditions of the real-world cyber-physical system. In an embodiment, the computer system further comprises a GUI.

In another embodiment, a computer modeling system comprises a computer system further comprising: at least one processor and a computer-usable medium embodying computer program code, the computer-usable medium capable of communicating with the at least one processor, the computer program code comprising instructions executable by the at least one processor and configured for generating a predictive digital twin of a real-world cyber-physical system, wherein the real-world cyber-physical system is configured to auto-generate the predictive digital twin of itself and wherein the cyber-physical system is configured to be hierarchically joined with additional cyber-physical systems capable of auto generating additional predictive digital twins of themselves. In an embodiment, the computer modeling system is further configured for embedding the predictive digital twin in a model virtual world. In an embodiment, the model virtual world comprises at least one of a model of an environment, a model of physical devices in the environment, a model of computer systems in the environment, a model of network components associated with the computer systems and a copy of software associated with the computer systems. In an embodiment, the computer modeling system is further configured for generating at least one additional predictive digital twin comprising a copy of the predicative digital twin of the real-world cyber-physical. In an embodiment, the computer modeling system is further configured for simulating changes to the real-world cyber-physical system using the predictive digital twin(s) and uploading software-only components to the real-world cyber-physical system based on the results of the simulations. In an embodiment, simulating changes to the real-world cyber-physical system further comprises at least one of simulating perturbations to the cyber-physical system and simulating different operating conditions of the real-world cyber-physical system.

In another embodiment, a computer implemented method comprises generating a predictive digital twin of a real-world cyber-physical system, simulating changes to the real-world cyber-physical system in a virtual world using the predictive digital twin, and uploading software-only components to the real-world cyber-physical system based on the results of the simulations. In an embodiment, the computer implemented method further comprises automatically generating a predictive digital twin.

It should be appreciated that variations of the above-disclosed and other features and functions, or alternatives thereof, may be desirably combined into many other different systems or applications. It should be understood that various presently unforeseen or unanticipated alternatives, modifications, variations, or improvements therein may be subsequently made by those skilled in the art which are also intended to be encompassed by the following claims.

What is claimed is:

1. A system comprising:
a computer system further comprising:
at least one processor; and
a computer-usable medium embodying computer program code, the computer-usable medium capable of communicating with the at least one processor, the computer program code comprising instructions executable by the at least one processor and configured for:
identifying a real-world cyber-physical system;
generating a predictive digital twin of the real-world cyber-physical system;
simulating changes to the real-world cyber-physical system using the predictive digital twin(s); and
uploading software-only components to the real-world cyber-physical system based on results of the simulations.

2. The system of claim 1 wherein generating a predictive digital twin of the real-world cyber-physical system further comprises:
automatically generating the predictive digital twin.

3. The system of claim 2 wherein automatically generating the predictive digital twin of the real-world cyber-physical system further comprises:
creating copies of software-only components of the real-world cyber-physical system.

4. The system of claim 3 wherein automatically generating the predictive digital twin further comprises:
modeling at least one computer associated with the real-world cyber-physical system used to run the software-only components of the real-world cyber-physical system.

5. The system of claim 4 wherein modeling computers associated with the real-world cyber-physical system comprises:
requisitioning a stateful container; and
putting the stateful container into a same state as the modeled computer by copying all files from a given software container in the real-world cyber-physical system to the modeled computer in the predictive digital twin of the real-world cyber-physical system.

6. The system of claim 2 wherein automatically generating the predictive digital twin of the real-world cyber-physical system further comprises:
generating a software model of each hardware component used in the real-world cyber-physical system.

7. The system of claim 6 further comprising:
generating the software model of each hardware component used in the real-world cyber-physical system using run-time accessible state information from the real-world cyber-physical system.

8. The system of claim 2 wherein automatically generating the predictive digital twin of the real-world cyber-physical system further comprises:
modeling a communications network of the real-world cyber-physical system.

9. The system of claim 8 wherein modeling a communications network of the real-world cyber-physical system further comprises:
artificially imposing limitations on corresponding communications links within the predictive digital twin.

10. The system of claim 1 wherein simulating changes to the real-world cyber-physical system further comprises:
simulating perturbations to the cyber-physical system.

11. The system of claim 1 wherein simulating changes to the real-world cyber-physical system further comprises:
simulating different operating conditions of the real-world cyber-physical system.

12. The system of claim 1 wherein the computer system further comprises a GUI.

13. A computer modeling system comprising:
A computer system further comprising:
at least one processor; and
a computer-usable medium embodying computer program code, the computer-usable medium capable of communicating with the at least one processor, the computer program code comprising instructions executable by the at least one processor and configured for:
generating a predictive digital twin of a real-world cyber-physical system, wherein the real-world cyber-physical system is configured to auto-generate the predictive digital twin of itself and wherein the real-world cyber-physical system is configured to be hierarchically joined with additional real-world cyber-physical systems capable of auto generating additional predictive digital twins of themselves.

14. The computer modeling system of claim 13 further comprising:
embedding the predictive digital twin in a model virtual world.

15. The computer modeling system of claim 14 wherein the model virtual world comprises at least one of:
a model of an environment;
a model of physical devices in the environment;
a model of computer systems in the environment;
a model of network components associated with the computer systems; and
a copy of software associated with the computer systems.

16. The computer modeling system of claim 13 further comprising:
generating at least one additional predictive digital twin comprising a copy of the predicative digital twin of the real-world cyber-physical system.

17. The computer modeling system of claim 13 further comprising:
simulating changes to the real-world cyber-physical system using the predictive digital twin(s); and
uploading software-only components to the real-world cyber-physical system based on the results of the simulations.

18. The computer modeling system of claim 17 wherein simulating changes to the real-world cyber-physical system further comprises at least one of:
simulating perturbations to the real-world cyber-physical system; and
simulating different operating conditions of the real-world cyber-physical system.

19. A computer implemented method comprising:
generating a predictive digital twin of a real-world cyber-physical system;
simulating changes to the real-world cyber-physical system in a virtual world using the predictive digital twin; and
uploading software-only components to the real-world cyber-physical system based on results of the simulations.

20. The computer implemented method of claim 19 further comprising:
automatically generating a predictive digital twin.
